(19) United States
(12) Patent Application Publication
(10) Pub. No.: US 2026/0271583 A1
(43) Pub. Date: Sep. 10, 2026

(54) DISPLAY DEVICE AND ELECTRONIC DEVICE USING THE DISPLAY DEVICE

(71) Applicant: Samsung Display Co., LTD., Yongin-si (KR)

(72) Inventors: Joon Gu LEE, Yongin-si (KR); Hye Jin GWARK, Yongin-si (KR); Hwi KIM, Yongin-si (KR); Jung Sun PARK, Yongin-si (KR); Ji Hee SON, Yongin-si (KR); A Reum LEE, Yongin-si (KR)

(21) Appl. No.: 19/408,660

(22) Filed: Dec. 4, 2025

(30) Foreign Application Priority Data
Mar. 5, 2025 (KR) 10-2025-0027836
Apr. 24, 2025 (KR) 10-2025-0053719

(51) Int. Cl. H10K 59/80; H10K 59/122

(52) U.S. Cl. CPC H10K 59/80523; H10K 59/122

(57) ABSTRACT

There is provided a display device. The display device includes a substrate comprising an emission area and a non-emission area; a plurality of anodes located on the emission area of the substrate; a light emitting layer located on the anodes and comprising a first light emitting layer and a second light emitting layer spaced apart from each other; and a cathode comprising a first cathode located on the first light emitting layer and a second cathode located on the second light emitting layer and spaced apart from the first cathode, wherein the cathode comprises 90% to 100% silver (Ag), silver content of the first cathode and silver content of the second cathode are different from each other, and a thickness of an electron transport layer of the first light emitting layer and a thickness of an electron transport layer of the second light emitting layer are different from each other.

This application claims priority to Korean Patent Application No. 10-2025-0027836, filed on March 5, 2025, and Korean Patent Application No. 10-2025-0053719, filed on April 24, 2025, and all the benefits accruing therefrom under 35 U.S.C. §119, the contents of which in their entirety are herein incorporated by reference.

### BACKGROUND

### 1. Field

The present disclosure relates to a display device and an electronic device using the display device.

### 2. Description of the Related Art

As the information society develops, demand for display devices for displaying images in various forms is increasing. For example, display devices are applied to various electronic devices such as smartphones, digital cameras, notebook computers, navigation devices, and smart televisions. The display devices may be flat panel display devices such as liquid crystal display devices, field emission display devices, and organic light emitting display devices. Among these flat panel display devices, a light emitting display device includes a light emitting element that enables each pixel of a display panel to emit light by itself. Thus, the light emitting display device can display an image without a backlight unit for providing light to the display panel.

With the recent development of various electronic devices, the demand for high-resolution display devices is increasing. Since high-resolution display devices may be implemented to have a high pixel density, a gap between light emitting elements respectively overlapping emission areas may be reduced. Therefore, a high-resolution display device may be formed by a patterning process for forming individual pixels rather than a process using a fine metal mask.

### SUMMARY

Aspects of the present disclosure are to provide a high-resolution display device and secure optimal light efficiency of a light emitting element.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

In an embodiment of the disclosure, a display device includes a substrate including an emission area and a non-emission area; a plurality of anodes located on the emission area of the substrate; a light emitting layer located on the anodes and including a first light emitting layer and a second light emitting layer spaced apart from each other; and a cathode including a first cathode located on the first light emitting layer and a second cathode located on the second light emitting layer and spaced apart from the first cathode, wherein the cathode includes 90% to 100% silver (Ag), silver content of the first cathode and silver content of the second cathode are different from each other, and a thickness of an electron transport layer of the first light emitting layer and a thickness of an electron transport layer of the second light emitting layer are different from each other.

In an embodiment, the silver content of the second cathode may be higher than the silver content of the first cathode, and the thickness of the electron transport layer of the second light emitting layer has a smaller value than the thickness of the electron transport layer of the first light emitting layer.

In an embodiment, the display device may further include a third light emitting layer spaced apart from the first light emitting layer and the second light emitting layer; and a third cathode located on the third light emitting layer and spaced apart from the first cathode and the second cathode, wherein silver content of the third cathode is higher than the silver content of the second cathode, and a thickness of an electron transport layer of the third light emitting layer has a smaller value than the thickness of the electron transport layer of the second light emitting layer.

In an embodiment, the display device may further include a third light emitting layer spaced apart from the first light emitting layer and the second light emitting layer; and a third cathode located on the third light emitting layer and spaced apart from the first cathode and the second cathode, wherein silver content of the third cathode is equal to the silver content of the second cathode, and a thickness of an electron transport layer of the third light emitting layer is equal to the thickness of the electron transport layer of the second light emitting layer.

In an embodiment, the display device may include a pixel defining layer located on the cathode and defining one or more emission openings, wherein the first light emitting layer and the second light emitting layer are spaced apart from each other by a portion of the pixel defining layer located between the first light emitting layer and the second light emitting layer, and the first cathode and the second cathode are spaced apart from each other by a portion of the pixel defining layer located between the first cathode and the second cathode.

In an embodiment, the display device may include a cathode auxiliary electrode located on the cathode, wherein the cathode auxiliary electrode contacts the first cathode at a portion of the cathode auxiliary electrode overlapping an emission opening associated with the first cathode, contacts the second cathode at a portion of the cathode auxiliary electrode overlapping an emission opening associated with the second cathode, and electrically connects the first cathode and the second cathode.

In an embodiment, a distance between the first cathode and a first anode of the plurality of anodes has a greater value than a distance between the second cathode and a second anode of the plurality of anodes.

In an embodiment, the light emitting layer may include a first portion located on the anodes and including a hole transport layer and an organic light emitting layer; a second portion located on the first portion and including the electron transport layer of the first light emitting layer and the electron transport layer of the second light emitting layer; and a third portion located between the second portion and the cathode and including an electron injection layer.

In an embodiment, the first portion of the light emitting layer may include a plurality of organic light emitting layers; and a charge transport layer located between the plurality of organic light emitting layers.

In an embodiment, a thickness of the second portion of the first light emitting layer may have a greater value than a thickness of a second portion of the second light emitting layer.

In an embodiment, the display device may further include a bank structure located between the substrate and the anodes, wherein the bank structure includes: a first bank layer; a second bank layer; and a third bank layer including a tip protruding toward the non-emission area more than a side surface of the second bank layer.

In an embodiment, the light emitting layer and the cathode may be located on the bank structure, and the cathode contacts the tip of the third bank layer.

In an embodiment, the display device may include an element insulating layer located between the anodes and the bank structure; and a pixel defining layer located on the element insulating layer and covering edges of the anodes, wherein the light emitting layer covers upper and side surfaces of the pixel defining layer and contacts side surfaces of the element insulating layer.

In an embodiment, the cathode may have a semi-transmissive characteristic.

In an embodiment, the cathode further may include at least any one of magnesium, ytterbium, lithium, samarium, sodium, or calcium.

In an embodiment of the disclosure, an electronic device include at least one display device including a substrate which includes an emission area and a non-emission area; and at least any one of a display module, a processor, a memory, or a power module connected to the display device, wherein the at least one display device includes: a plurality of anodes located on the emission area of the substrate; a light emitting layer located on the anodes and including a first light emitting layer and a second light emitting layer spaced apart from each other; and a cathode including a first cathode located on the first light emitting layer and a second cathode located on the second light emitting layer and spaced apart from the first cathode, wherein the cathode includes 90% to 100% silver (Ag), silver content of the first cathode and silver content of the second cathode are different from each other, and a thickness of an electron transport layer of the first light emitting layer and a thickness of an electron transport layer of the second light emitting layer are different from each other.

In a display device according to an embodiment and an electronic device using the display device, a plurality of light emitting elements are formed by photolithography. Therefore, a high-resolution display device can be provided.

In a display device according to an embodiment and an electronic device using the display device, optimal light efficiency of light emitting elements may be secured by forming first through third cathodes to have different silver content and adjusting thicknesses of electron transport layers of light emitting layers according to the silver content.

However, the effects of the present disclosure are not restricted to the one set forth herein. The above and other effects of the present disclosure will become more apparent to one of daily skill in the art to which the present disclosure pertains by referencing the detailed description of the present disclosure given below.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of a display device according to an embodiment;

FIG. 2 is a schematic cross-sectional view of the display device of FIG. 1;

FIG. 3 is a plan view illustrating the arrangement of emission areas in a display area of FIG. 2;

FIG. 4 is a schematic cross-sectional view taken along line X1-X1’ of FIG. 3;

FIG. 5 is a schematic cross-sectional view of a light emitting layer according to an embodiment;

FIG. 6 is a schematic cross-sectional view of a light emitting layer according to an embodiment;

FIG. 7 is an enlarged cross-sectional view of a display element layer overlapping a first emission area and a second emission area in FIG. 4;

FIG. 8 is a graph illustrating the light penetration depth of a cathode of an embodiment;

FIG. 9 is a diagram illustrating the light penetration depth according to the silver content of the cathode;

FIG. 10 is an enlarged cross-sectional view of the display element layer overlapping the second emission area and a third emission area in FIG. 4;

FIG. 11 is a graph illustrating the change in luminous efficiency of first through third light emitting elements when thicknesses of a first portion, a second portion and a third portion of a light emitting layer are adjusted;

FIG. 12 is an enlarged cross-sectional view of a display element layer overlapping the second emission area and the third emission area in FIG. 4 according to an embodiment;

FIG. 13 is a schematic cross-sectional view taken along line X1-X1’ of FIG. 3 according to an embodiment;

FIG. 14 is an enlarged cross-sectional view of a display element layer overlapping a first emission area and a second emission area in FIG. 13;

FIG. 15 is an enlarged cross-sectional view of the display element layer overlapping the second emission area and a third emission area in FIG. 13;

FIG. 16 is an enlarged cross-sectional view of a display element layer overlapping the second emission area and the third emission area in FIG. 13 according to an embodiment;

FIG. 17 is a block diagram of an electronic device according to an embodiment; and

FIG. 18 is a schematic diagram of electronic devices according to various embodiments.

### DETAILED DESCRIPTION

Advantages and features of the present disclosure and methods of accomplishing the same may be understood more readily by reference to the following detailed description of embodiments and the accompanying drawings. The present disclosure may, however, be embodied in many different forms and should not be construed as being limited to the embodiments set forth herein. Rather, the example embodiments are provided such that this disclosure will be thorough and complete and will fully convey the concept of the present disclosure to those skilled in the art, and the present disclosure will be defined by the appended claims.

It will be understood that when an element or layer is referred to as being "on” another element or layer, the element or layer can be directly on another element or layer or intervening elements or layers. Like reference numerals refer to like elements throughout the specification. Shapes, sizes, ratios, angles, numbers, and the like disclosed in the drawings for describing embodiments are an example, and the present disclosure is not limited to the illustrated details.

It will be understood that, although the terms first, second, third, and the like, may be used herein to describe various elements, these elements should not be limited by these terms. These terms are used to distinguish one element from another element. Thus, a first element discussed below could be termed a second element without departing from the teachings of the present disclosure.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within ± 30%, 20%, 10%, 5% of the stated value, for example.

It is to be understood that characteristics described herein with respect to relative terms such as, for example, “high,” “low,” and the like may refer to the characteristics satisfying (e.g., being greater than, less than, or the like) a threshold associated with the characteristics or may refer to a relative level of the characteristics.

Features of various embodiments of the present disclosure may be partially or entirely coupled to or combined with each other, and may be inter-operated and driven in technically various ways. The embodiments may be implemented independently from each other, or may be implemented together in a co-dependent relationship.

Hereinafter, specific embodiments will be described with reference to the accompanying drawings.

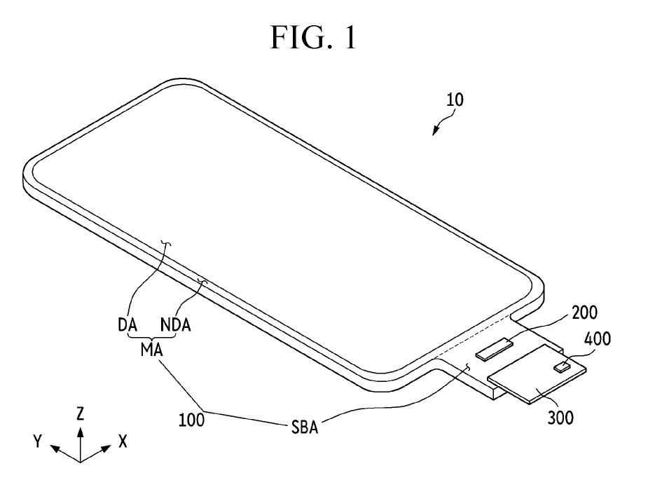

FIG. 1 is a perspective view of a display device 10 according to an embodiment.

Referring to FIG. 1, the display device 10 displays moving images or still images. The display device 10 may refer to any electronic device that provides a display screen. Examples of the display device 10 may include televisions, notebook computers, monitors, billboards, Internet of things (IoT) devices, mobile phones, smartphones, tablet personal computers (PCs), electronic watches, smart watches, watch phones, head mounted displays, mobile communication terminals, electronic notebooks, electronic books, portable multimedia players (PMPs), navigation devices, game machines, digital cameras and camcorders, all of which provide a display screen.

In FIG. 1, a first direction (X-axis direction), a second direction (Y-axis direction), and a third direction (Z-axis direction) are defined. The first direction (X-axis direction) and the second direction (Y-axis direction) may be perpendicular to each other, the first direction (X-axis direction) and the third direction (Z-axis direction) may be perpendicular to each other, and the second direction (Y-axis direction) and the third direction (Z-axis direction) may be perpendicular to each other. It may be understood that the first direction (X-axis direction) refers to a horizontal direction in the drawing, the second direction (Y-axis direction) refers to a vertical direction in the drawing, and the third direction (Z-axis direction) refers to an up-down direction in the drawing, that is, a thickness direction. In the following specification, unless otherwise specified, a “direction” may refer to both directions extending to both sides along the direction. For descriptions distinguishing both “directions” extending to both sides, one side will be referred to as “one side in the direction,” and the other side will be referred to as “the other side in the direction.” Based on FIG. 1, a direction indicated by an arrow will be referred to as one side, and the opposite direction will be referred to as the other side.

For ease of description below, in referring to surfaces of each member constituting the display device 10, one surface facing one side in a direction in which an image is displayed, that is, in the third direction (Z-axis direction) is referred to as an upper surface, and a surface opposite the one surface is referred to as the other surface. However, the present disclosure is not limited to this case, and the one surface and the other surface of each member may also be referred to as a front surface and a rear surface or as a first surface and a second surface, respectively. In describing relative positions of the members of the display device 10, one side in the third direction (Z-axis direction) may be referred to as an upper side, and the other side in the third direction (Z-axis direction) may be referred to as a lower side.

The shape of the display device 10 can be variously modified. For example, the display device 10 may have various shapes such as a horizontally long rectangle, a vertically long rectangle, a square, a quadrilateral with rounded corners (vertices), other polygons, and a circle.

The display device 10 may include a display panel 100, a display driver 200, a circuit board 300, and a touch driver 400.

The display panel 100 may include a main area MA and a sub-area SBA. The main area MA may include a display area DA including pixels that display an image and a non-display area NDA located around the display area DA. The main area MA and the sub-area SBA may include a flexible material that can be bent, folded, rolled, and the like.

The display area DA is an area where a screen can be displayed, and the non-display area NDA is an area where no screen is displayed. The display area DA may also be referred to as an active area, and the non-display area NDA may also be referred to as an inactive area. The display area DA may generally occupy the center of the display device 10. The non-display area NDA may be an area outside the display area DA. The non-display area NDA may be defined as an edge area of the main area MA of the display panel 100. The non-display area NDA may include lines that supply signals to the display area DA and lines that connect the display driver 200 to the display area DA.

The sub-area SBA may be an area extending from one side of the main area MA. In an example in which the sub-area SBA is bent, the sub-area SBA may be overlapped by the main area MA in the thickness direction (e.g., the third direction (Z-axis direction)). The sub-area SBA may include the display driver 200 and display pads connected to the circuit board 300. In an embodiment, the sub-area SBA may be omitted, and the display driver 200 and the display pads may be located in the non-display area NDA.

The display driver 200 may output signals and voltages for driving the display panel 100. The display driver 200 may be formed as an integrated circuit and mounted on the display panel 100 using a chip on glass (COG) method, a chip on plastic (COP) method, or an ultrasonic bonding method. For example, the display driver 200 may be located in the sub-area SBA and may be overlapped by the main area MA in the thickness direction by the bending of the sub-area SBA. In another example, the display driver 200 may be mounted on the circuit board 300.

The circuit board 300 may be attached onto the display pads of the display panel 100 using an anisotropic conductive film. The circuit board 300 may be electrically connected to the display pads. The circuit board 300 may be a flexible printed circuit board, a printed circuit board, or a flexible film such as a chip on film.

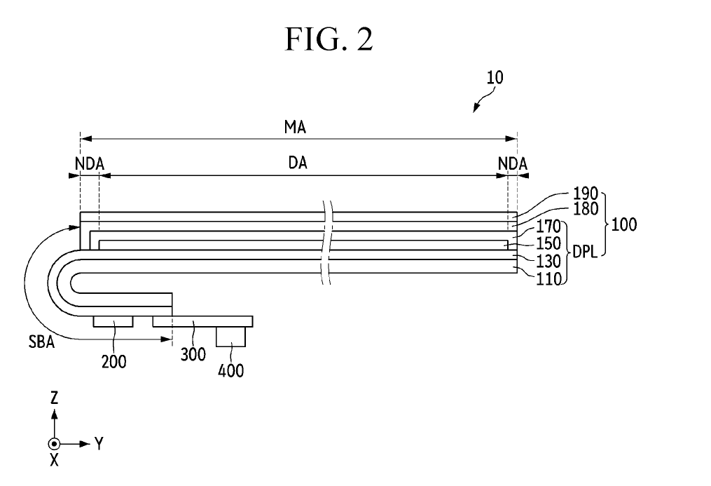

The touch driver 400 may be mounted on the circuit board 300. The touch driver 400 may be connected to a touch sensor layer 180 (see FIG. 2) of the display panel 100.

FIG. 2 is a schematic cross-sectional view of the display device 10 of FIG. 1.

Referring to FIG. 2, the display panel 100 may include a display layer DPL, the touch sensor layer 180, and a color filter layer 190. The display layer DPL may include a substrate 110, a thin-film transistor layer 130, a display element layer 150, and a thin-film encapsulation layer 170.

The substrate 110 may be a base substrate or a base member. The substrate 110 may be a flexible substrate that can be bent, folded, rolled, and the like. For example, the substrate 110 may include polymer resin such as polyimide (PI). However, the present disclosure is not limited to this example. In an embodiment, the substrate 110 may include a glass material or a metal material.

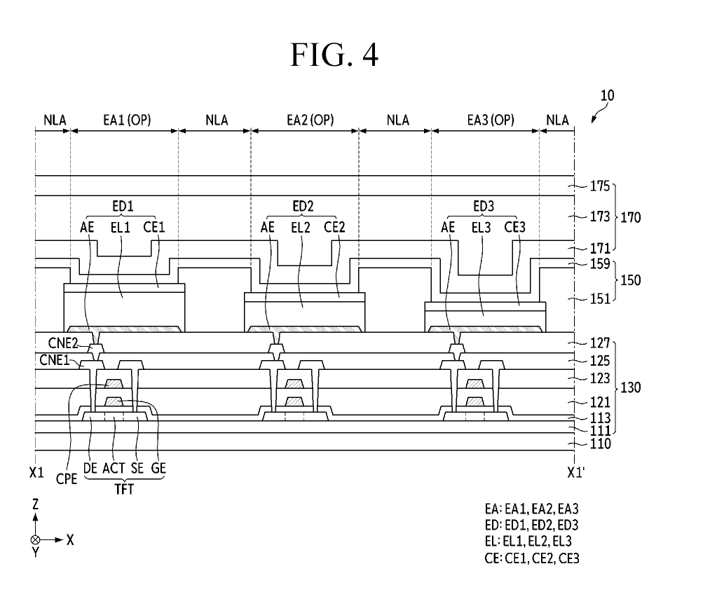

The thin-film transistor layer 130 may be located on the substrate 110. The thin-film transistor layer 130 may be located in portions overlapping the display area DA, the non-display area NDA, and the sub-area SBA. The thin-film transistor layer 130 may include a plurality of thin-film transistors TFT (see FIG. 4).

The display element layer 150 may be located on the thin-film transistor layer 130. The display element layer 150 may be located in the portion overlapping the display area DA. The display element layer 150 may include, but is not limited to, at least one of an organic light emitting diode including an organic light emitting layer, a quantum dot light emitting diode including a quantum dot light emitting layer, an inorganic light emitting diode including an inorganic semiconductor, and a micro-light emitting diode.

The thin-film encapsulation layer 170 may be located on the display element layer 150. The thin-film encapsulation layer 170 may be located in the portions overlapping the display area DA and the non-display area NDA. The thin-film encapsulation layer 170 may cover upper and side surfaces of the display element layer 150 and protect the display element layer 150 from external oxygen and moisture. The thin-film encapsulation layer 170 may include at least one inorganic layer and at least one organic layer to encapsulate the display element layer 150.

The touch sensor layer 180 may be located on the thin-film encapsulation layer 170. The touch sensor layer 180 may be located in the portions overlapping the display area DA and the non-display area NDA. The touch sensor layer 180 may sense a user’s touch using a mutual capacitance method or a self-capacitance method.

The color filter layer 190 may be located on the touch sensor layer 180. The color filter layer 190 may be located in the portions overlapping the display area DA and the non-display area NDA. The color filter layer 190 may absorb some of the light incident from the outside of the display device 10, thereby reducing reflected light caused by the external light. Therefore, the color filter layer 190 can prevent color distortion caused by the reflection of external light.

Since the color filter layer 190 is directly located on the touch sensor layer 180, the display device 10 may be implemented without a separate substrate for the color filter layer 190. Therefore, a thickness of the display device 10 may be relatively small. The color filter layer 190 can be omitted depending on embodiments.

As illustrated in FIG. 2, a portion of the display layer DPL which overlaps the sub-area SBA may be bent. In an example in which a portion of the display layer DPL is bent, the display driver 200, the circuit board 300, and the touch driver 400 may be overlapped by the main area MA in the third direction (Z-axis direction).

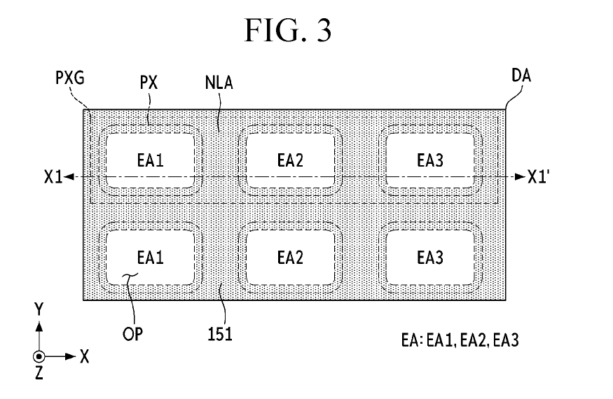

FIG. 3 is a plan view illustrating the arrangement of emission areas EA in the display area DA of FIG. 2.

Referring to FIG. 3, the display area DA of an embodiment may include emission areas EA and a non-emission area NLA. The non-emission area NLA may surround first through third emission areas EA1 through EA3.

The non-emission area NLA may block light emitted from each of the first through third emission areas EA1 through EA3. Therefore, the non-emission area NLA may help prevent the color mixing of light emitted from the first through third emission areas EA1 through EA3.

The emission areas EA may include the first emission areas EA1, the second emission areas EA2, and the third emission areas EA3, which emit light of different colors. Each of the first through third emission areas EA1 through EA3 may emit red, green, or blue light. The color of light emitted from each of the first through third emission areas EA1 through EA3 may vary according to the type of light emitting element ED (see FIG. 4) which will be described later. Although the first through third emission areas EA1 through EA3 have the same size and shape in the drawing, the present disclosure is not limited to this case. The size and shape of each of the first through third emission areas EA1 through EA3 can be freely adjusted according to desired or target characteristics.

At least one first emission area EA1, at least one second emission area EA2, and at least one third emission area EA3 located adjacent to each other may form one pixel group PXG. The pixel group PXG may be a smallest unit that emits white light. The type and/or number of the first through third emission areas EA1 through EA3 constituting the pixel group PXG may vary depending on embodiments.

In a plan view, a pixel defining layer 151 may be located in a portion of each of the emission areas EA and a portion overlapping the non-emission area NLA. The pixel defining layer 151 may define emission openings OP in the plan view. The pixel defining layer 151 may surround the emission openings OP.

FIG. 4 is a schematic cross-sectional view taken along line X1-X1’ of FIG. 3. FIG. 4 is a partial cross-sectional view of the display device 10 overlapping the display area DA of FIG. 3 and illustrates a schematic cross-section of the display layer DPL. That is, FIG. 4 illustrates cross-sections of the substrate 110, the thin-film transistor layer 130, the display element layer 150, and the thin-film encapsulation layer 170 located in a portion overlapping the display area DA (see FIG. 3) included in the display device 10. Since the substrate 110 has already been described, a redundant description of the substrate 110 will be omitted.

Referring to FIG. 4 in addition to FIGS. 1 through 3, the thin-film transistor layer 130 may be located on the substrate 110. The thin-film transistor layer 130 may include a first buffer layer 111, thin-film transistors TFT, a gate insulating layer 113, a first interlayer insulating layer 121, capacitor electrodes CPE, a second interlayer insulating layer 123, first connection electrodes CNE1, a first via layer 125, second connection electrodes CNE2, and a second via layer 127.

The first buffer layer 111 may be located on the substrate 110. The first buffer layer 111 may include an inorganic layer that can prevent the penetration of air or moisture. For example, the first buffer layer 111 may include a plurality of inorganic layers stacked alternately.

The thin-film transistors TFT may be located on the first buffer layer 111 and may constitute pixel circuits connected to a plurality of pixels, respectively. For example, each of the thin-film transistors TFT may be a driving transistor or a switching transistor of a pixel circuit. Each of the thin-film transistors TFT may include an active layer ACT, a source electrode SE, a drain electrode DE, and a gate electrode GE.

The active layer ACT may be located on the first buffer layer 111. The active layer ACT may be overlapped by the gate electrode GE in the third direction (Z-axis direction) and may be insulated from the gate electrode GE by the gate insulating layer 113. In portions of the active layer ACT, the material of the active layer ACT may be made conductive to form the source electrode SE and the drain electrode DE.

The gate electrode GE may be located on the gate insulating layer 113. The gate electrode GE may overlap the active layer ACT with the gate insulating layer 113. The gate insulating layer 113 may be located between the gate electrode GE and the active layer ACT.

The gate insulating layer 113 may be located on the active layers ACT. The gate insulating layer 113 may cover the active layers ACT and the first buffer layer 111 and may insulate the active layers ACT from the gate electrodes GE. The gate insulating layer 113 may include contact holes through which the first connection electrodes CNE1 pass.

The first interlayer insulating layer 121 may cover the gate electrodes GE and the gate insulating layer 113. The first interlayer insulating layer 121 may include contact holes through which the first connection electrodes CNE1 pass. The contact holes of the first interlayer insulating layer 121 may be connected to the contact holes of the gate insulating layer 113 and contact holes of the second interlayer insulating layer 123.

The capacitor electrodes CPE may be located on the first interlayer insulating layer 121. The capacitor electrodes CPE may overlap the gate electrodes GE in the third direction (Z-axis direction). The capacitor electrodes CPE and the gate electrodes GE may form capacitance.

The second interlayer insulating layer 123 may cover the capacitor electrodes CPE and the first interlayer insulating layer 121. The second interlayer insulating layer 123 may include the contact holes through which the first connection electrodes CNE1 pass. The contact holes of the second interlayer insulating layer 123 may be connected to the contact holes of the first interlayer insulating layer 121 and the contact holes of the gate insulating layer 113.

The first connection electrodes CNE1 may be located on the second interlayer insulating layer 123. The first connection electrodes CNE1 may electrically connect the drain electrodes DE of the thin-film transistors TFT to the second connection electrodes CNE2. The first connection electrodes CNE1 may be inserted into the contact holes formed in the first interlayer insulating layer 121, the second interlayer insulating layer 123 and the gate insulating layer 113 to contact the drain electrodes DE of the thin-film transistors TFT.

The first via layer 125 may cover the first connection electrodes CNE1 and the second interlayer insulating layer 123. The first via layer 125 may planarize the structures under the first via layer 125. The first via layer 125 may include contact holes through which the second connection electrodes CNE2 pass.

The second connection electrodes CNE2 may be located on the first via layer 125. The second connection electrodes CNE2 may be inserted into the contact holes formed in the first via layer 125 to contact the first connection electrodes CNE1. The second connection electrodes CNE2 may electrically connect the first connection electrodes CNE1 to anodes AE.

The second via layer 127 may cover the second connection electrodes CNE2 and the first via layer 125. The second via layer 127 may include contact holes through which the anodes AE pass.

The display element layer 150 may be located on the second via layer 127. The display element layer 150 may include light emitting elements ED, the pixel defining layer 151, and a cathode auxiliary electrode 159.

Each of the light emitting elements ED may include an anode AE, a light emitting layer EL, and a cathode CE. The light emitting elements ED may include a first light emitting element ED1 located in a first emission area EA1, a second light emitting element ED2 located in a second emission area EA2, and a third light emitting element ED3 located in a third emission area EA3.

The first through third light emitting elements ED1 through ED3 may emit light of different colors depending on the materials of the light emitting layers EL. For example, the first light emitting element ED1 may emit red light, the second light emitting element ED2 may emit green light, and the third light emitting element ED3 may emit blue light.

The anodes AE may be located on the second via layer 127. The anodes AE may be electrically connected to the drain electrodes DE of the thin-film transistors TFT through the first connection electrodes CNE1 and the second connection electrodes CNE2.

A plurality of anodes AE may be formed. The anodes AE may be formed in portions overlapping the first through third emission areas EA1 through EA3, respectively, and may be spaced apart from each other.

The anodes AE may have a stacked structure of a material layer having a high work function such as indium-tin-oxide (ITO), indium-zinc-oxide (IZO), zinc oxide (ZnO) or indium oxide (In₂O₃) and a reflective material layer such as silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), calcium (Ca) or a mixture thereof. For example, the anodes AE may have, but are not limited to, a multilayer structure of ITO/Mg, ITO/MgF, ITO/Ag, or ITO/Ag/ITO.

The light emitting layers EL of an embodiment may be located on the anodes AE. The light emitting layers EL may include a first light emitting layer EL1, a second light emitting layer EL2 and a third light emitting layer EL3 located in the first, second and third emission areas EA1, EA2 and EA3, respectively. The first light emitting layer EL1, the second light emitting layer EL2, and the third light emitting layer EL3 may emit light of different colors. For example, the first light emitting layer EL1 may emit red light, the second light emitting layer EL2 may emit green light, and the third light emitting layer EL3 may emit blue light. However, the present disclosure is not limited to this example.

The light emitting layers EL of the embodiment may be formed through a photolithography process during a manufacturing process. In other words, the light emitting layers EL may be formed through a photo process and an etching process without using a separate fine metal mask.

The display device 10 of the embodiment may be applied to a high-resolution electronic device 1. Therefore, a plurality of light emitting elements ED included in the display element layer 150 may be specified to lie within a narrow area with an appropriate distance secured between the light emitting elements ED. Accordingly, the light emitting layers EL may be formed by a photolithography process, and thus the display device 10 may include a plurality of light emitting layers EL located within a narrow area with an appropriate distance secured between the light emitting layers EL.

In some aspects, since the light emitting layers EL of the embodiment are formed through the photolithography process during the manufacturing process, the first through third light emitting layers EL1 through EL3 may have different thickness characteristics. This will be described in detail later.

The cathodes CE may be located on the light emitting layer EL. The cathodes CE of an embodiment may be formed integrally with the light emitting layers EL. The cathodes CE may include a first cathode CE1, a second cathode CE2 and a third cathode CE3 located in the first, second and third emission areas EA1, EA2 and EA3, respectively. The first cathode CE1, the second cathode CE2, and the third cathode FCE3 of the embodiment may be spaced apart from each other by the pixel defining layer 151. The pixel defining layer 151 may be located between the first cathode CE1, the second cathode CE2, and the third cathode CE3.

The cathodes CE of the embodiment may include a metal material having a semi-transmissive characteristic. For example, the cathodes CE may include silver (Ag). In some aspects, the cathodes CE may further include at least any one of magnesium (Mg), ytterbium (Yb), lithium (Li), samarium (Sm), sodium (Na), or calcium (Ca).

The cathodes CE of the embodiment may be formed through a photolithography process during the manufacturing process. In other words, the cathodes CE may be formed through a photo process and an etching process without using a separate fine metal mask. Accordingly, the cathodes CE of the embodiment may include the first through third cathodes CE1 through CE3 spaced apart from each other and located in the first through third emission areas EA1 through EA3, respectively, and the first through third cathodes CE1 through CE3 may have different material compositions. This will be described in detail later.

The cathode auxiliary electrode 159 may be located on the cathodes CE. The cathode auxiliary electrode 159 may be formed as a common layer in the portions overlapping the emission areas EA and the non-emission area NLA. Accordingly, the cathode auxiliary electrode 159 may extend from the first through third cathodes CE1 through CE3 to contact the pixel defining layer 151.

The cathode auxiliary electrode 159 may contact the first through third cathodes CE1 through CE3 in portions respectively overlapping emission openings OP and may electrically connect the first through third cathodes CE1 through CE3.

The cathode auxiliary electrode 159 may receive a low-potential voltage and transmit the low-potential voltage to the first through third cathodes CE1 through CE3. For example, the anodes AE may receive voltages corresponding to data voltages, and the cathode auxiliary electrode 159 may receive a low-potential voltage and transmit the low-potential voltage to the first through third cathodes CE1 through CE3. In this case, a potential difference may be formed between the anodes AE and the cathodes CE, causing the light emitting layers EL to emit light.

The cathode auxiliary electrode 159 may include a transparent oxide electrode (TCO). For example, the cathode auxiliary electrode 159 may include any one of indium-tin-oxide (ITO), indium-zinc-oxide (IZO), or zinc-indium-tin-oxide (ZITO).

The pixel defining layer 151 may be located on the second via layer 127 in the portion overlapping the non-emission area NLA. The pixel defining layer 151 may cover edges of the cathodes CE and may extend from the edges of the cathodes CE to contact side surfaces of the light emitting layers EL. The pixel defining layer 151 may separate and insulate the first through third light emitting elements ED1 through ED3 from each other.

The pixel defining layer 151 may define the emission openings OP. The pixel defining layer 151 may surround the emission openings OP. The pixel defining layer 151 may expose the cathodes CE in the portions overlapping the emission openings OP.

The pixel defining layer 151 may include an organic material. For example, the pixel defining layer 151 may include silicone resin, acrylic resin, epoxy resin, or a mixture thereof.

The thin-film encapsulation layer 170 may be located on the display element layer 150. The thin-film encapsulation layer 170 may be located in the portions overlapping the emission areas EA and the non-emission area NLA. The thin-film encapsulation layer 170 may include a first encapsulation layer 171, an organic encapsulation layer 173, and an inorganic encapsulation layer 175 stacked sequentially.

The first encapsulation layer 171 may be located on the cathode auxiliary electrode 159. The first encapsulation layer 171 may have a uniform thickness along the profile of the structure under the first encapsulation layer 171 and may cover the structure. Therefore, the first encapsulation layer 171 may include steps.

The first encapsulation layer 171 may include one or more inorganic insulating materials and may prevent oxygen or moisture from penetrating into the light emitting elements ED. For example, the first encapsulation layer 171 may include any one of aluminum oxide, titanium oxide, tantalum oxide, hafnium oxide, zinc oxide, silicon oxide, silicon nitride, or silicon oxynitride.

The organic encapsulation layer 173 may be located on the first encapsulation layer 171. The organic encapsulation layer 173 may flatten the steps formed by the first encapsulation layer 171. In some aspects, the organic encapsulation layer 173 may protect the display element layer 150 from foreign substances.

The organic encapsulation layer 173 may include a polymer-based material. For example, the organic encapsulation layer 173 may include silicone resin, acrylic resin, epoxy resin, or a mixture thereof.

The inorganic encapsulation layer 175 may be located on the organic encapsulation layer 173. The inorganic encapsulation layer 175 may include one or more inorganic insulating materials and may prevent oxygen or moisture from penetrating into the display element layer 150 and the first encapsulation layer 171. The inorganic encapsulation layer 175 may include the same material as the first encapsulation layer 171. Redundant descriptions are omitted.

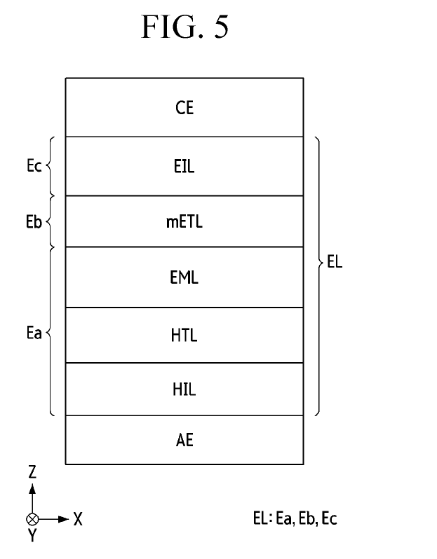

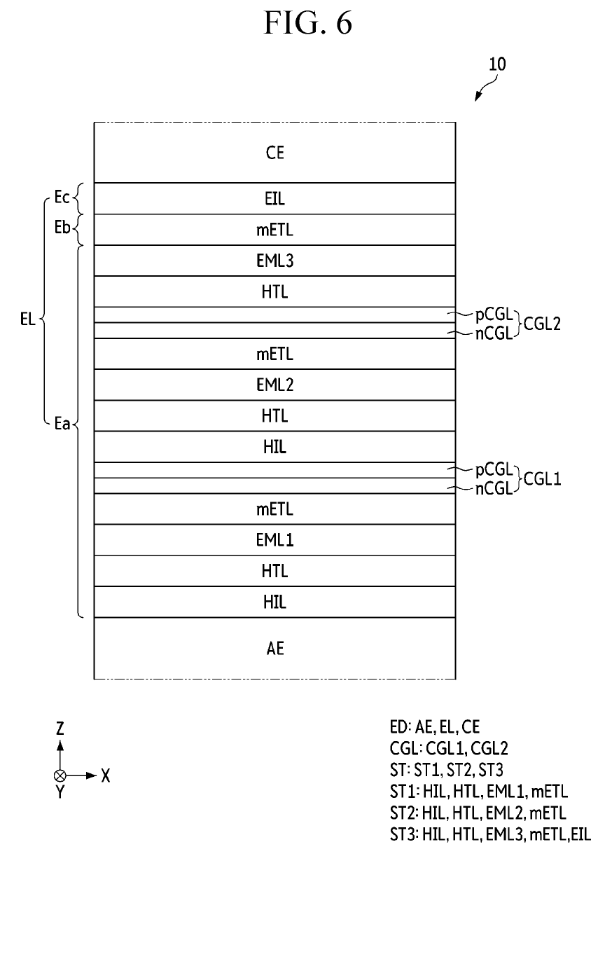

FIGS. 5 and 6 are schematic cross-sectional views of light emitting layers EL according to embodiments.

Referring to FIGS. 5 and 6 in addition to FIGS. 1 through 4, a light emitting layer EL according to an embodiment may include a first portion Ea, a second portion Eb, and a third portion Ec sequentially stacked in the third direction (Z-axis direction).

The first portion Ea may contact an anode AE, the third portion Ec may contact a cathode CE, and the second portion Eb may be located between the first portion Ea and the third portion Ec.

In some embodiments, the first portion Ea of the light emitting layer EL may include a hole injection layer HIL, a hole transport layer HTL, and an organic light emitting layer EML. The hole injection layer HIL may be located on the anode AE, the hole transport layer HTL may be located on the hole injection layer HIL, and the organic light emitting layer EML may be located on the hole transport layer HTL. According to an embodiment, the hole injection layer HIL and the hole transport layer HTL may be formed as a single layer to form a hole injection transport layer.

The hole injection layer HIL may assist in the smooth injection of holes from the anode AE into the organic light emitting layer EML. The hole injection layer HIL may be a single layer including a single material, a single layer including a plurality of different materials, or a multilayer structure having a plurality of layers respectively including different materials. The hole injection layer HIL of an embodiment may include any commonly used material.

The hole transport layer HTL may assist in the smooth transport of holes from the anode AE to the organic light emitting layer EML. The hole transport layer HTL may be a single layer including a single material, a single layer including a plurality of different materials, or a multilayer structure having a plurality of layers respectively including different materials. The hole transport layer HTL of an embodiment may include any commonly used material.

The organic light emitting layer EML emits light by combining electrons and holes. The organic light emitting layer EML may include a host material and a dopant material. The organic light emitting layer EML may use a phosphorescent or fluorescent light emitting material as a dopant in the host material and may emit light of different colors by combining the host material and the dopant material. The organic light emitting layer EML may include different materials in portions overlapping the first through third emission areas EA1 through EA3, respectively. Accordingly, the first through third light emitting layers EL1 through EL3 may emit light of different colors in the portions overlapping the first through third emission areas EA1 through EA3.

In an embodiment, the second portion Eb may include an electron transport layer mETL. The electron transport layer mETL may transport electrons received from the cathode CE to the light emitting layer EL. The electron transport layer mETL of an embodiment may include any commonly used material.

In an embodiment, the third portion Ec may include an electron injection layer EIL. The electron injection layer EIL may be located on the electron transport layer mETL.

The electron injection layer EIL may inject electrons received from the cathode CE into the light emitting layer EL. The electron injection layer EIL of an embodiment may include any commonly used material.

As illustrated in FIG. 6, in some embodiments, the light emitting layer EL may include a plurality of light emitting stacks ST. Each of the light emitting stacks ST may include a high-molecular or low-molecular organic material that emits light of a selected color. In addition to various organic materials, each of the light emitting stacks ST may further include a metal-containing compound such as an organometallic compound, an inorganic material such as quantum dots, and the like. Although a three (3)-tandem structure including three light emitting stacks ST is illustrated in the drawing, the current embodiment is not limited to this case. Two or fewer light emitting stacks ST may also be included, or four or more light emitting stacks ST may also be included.

The light emitting stacks ST may include a plurality of organic light emitting layers EML. For example, a first light emitting stack ST1 may include a first organic light emitting layer EML1, a second light emitting stack ST2 may include a second organic light emitting layer EML2 overlapping the first organic light emitting layer EML1, and a third light emitting stack ST3 may include a third organic light emitting layer EML3 overlapping the first organic light emitting layer EMLb and the second organic light emitting layer EML2.

In an example, the first organic light emitting layer EML1 may emit light of any one of a first color, a second color, or a third color, the second organic light emitting layer EML2 may emit light of any one of the first color, the second color, or the third color, and the third organic light emitting layer EML3 may emit light of any one of the first color, the second color, or the third color. According to an embodiment, the first organic light emitting layer EML1, the second organic light emitting layer EML2, and the third organic light emitting layer EML3 may emit light of the same color, or the first organic light emitting layer EML1, the second organic light emitting layer EML2, and the third organic light emitting layer EML3 may emit light of different colors. For example, light of the first color may be red light, light of the second color may be green light, and light of the third color may be blue light, but the present disclosure is not limited to this example.

In another example, the first organic light emitting layer EML1 may emit a plurality of light from among light of the first color, light of the second color, light of the third color and light of a fourth color, the second organic light emitting layer EML2 may emit a plurality of light from among the light of the first color, the light of the second color, the light of the third color and the light of the fourth color, and the third organic light emitting layer EML3 may emit a plurality of light from among the light of the first color, the light of the second color, the light of the third color and the light of the fourth color. For example, the light of the first color may be red light, the light of the second color may be green light, the light of the third color may be blue light, and the light of the fourth color may be yellow light, but the present disclosure is not limited to this example.

The light emitting stacks ST may further include one or more intermediate layers overlapping one or more organic light emitting layers EML. For example, the intermediate layers may include a hole injection layer HIL, a hole transport layer HTL, an electron transport layer mETL, and an electron injection layer EIL. Redundant descriptions are omitted.

The light emitting stacks ST may further include a charge generation layer CGL located between a plurality of organic light emitting layers EML. The charge generation layer CGL may be a functional layer that controls a charge balance between the light emitting stacks ST. Therefore, the charge generation layer CGL may provide charges to each of the first through third organic light emitting layers EML1 through EMLb, thereby increasing the luminous efficiency of a light emitting element ED and lowering the driving voltage of the light emitting element ED.

The charge generation layer CGL may include a first charge generation layer CGL1 located between the first light emitting stack ST1 and the second light emitting stack ST2 and a second charge generation layer CGL2 located between the second light emitting stack ST2 and the third light emitting stack ST3.

A negative charge generation layer nCGL included in the first charge generation layer CGL1 may contact the first light emitting stack ST1 to supply electrons to the first organic light emitting layer EML1 and may include a host and a dopant. The host may include an organic material, and the dopant may include a metal material. In an embodiment, the negative charge generation layer nCGL may include any material commonly used for the negative charge generation layer nCGL.

A positive charge generation layer pCGL included in the first charge generation layer CGL1 may contact the second light emitting stack ST2 to supply holes to the second organic light emitting layer EMLb and may include a host and a dopant. The host may include an organic material, and the dopant may include a metal material. In an embodiment, the positive charge generation layer pCGL may include any material commonly used for the positive charge generation layer pCGL.

A negative charge generation layer nCGL included in the second charge generation layer CGLb may contact the second light emitting stack ST2 to supply electrons to the second organic light emitting layer EML2. A positive charge generation layer pCGL included in the second charge generation layer CGL2 may contact the third light emitting stack ST3 to supply holes to the third organic light emitting layer EML3.

In an example in which the light emitting layer EL includes a plurality of light emitting stacks ST, the first portion Ea of the light emitting layer EL may include the first light emitting stack STb, the second light emitting stack STb, and the hole transport layer HTL and the third organic light emitting layer EML3 of the third light emitting stack STb, the second portion Eb may include the electron transport layer mETL of the third stack ST3, and the third portion Ec may include the electron injection layer EIL of the third stack ST3. Other redundant descriptions are omitted.

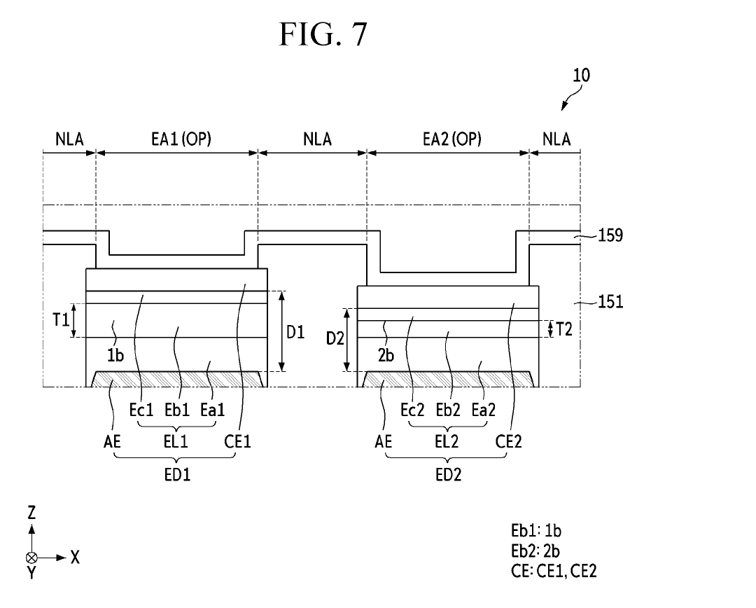

FIG. 7 is an enlarged cross-sectional view of the display element layer 150 overlapping the first emission area EA1 and the second emission area EA2 in FIG. 4.

Referring to FIG. 7 in addition to FIGS. 1 through 6, the anode AE, the first light emitting layer EL1 and the first cathode CE1 included in the first light emitting element ED1 of an embodiment and the anode AE, the second light emitting layer EL2 and the second cathode CE2 included in the second light emitting element ED2 may be spaced apart from each other by the pixel defining layer 151. The pixel defining layer 151 may be located between the anode AE, the first light emitting layer EL1 and the first cathode CEb included in the first light emitting element ED1 and the anode AE, the second light emitting layer EL2 and the second cathode CE2 included in the second light emitting element ED2.

As described herein, the cathodes CE of an embodiment may be formed by a photolithography process to have different material compositions. In other words, the silver (Ag) content of the first cathode CE1 and the silver (Ag) content of the second cathode CE2 may be different from each other.

Specifically, the first cathode CE1 may have a lower silver (Ag) content than the second cathode CE2. For example, the first cathode CE1 may include about 90% to 95% silver (Ag), and the second cathode CE2 may include about 95% or more silver (Ag). The silver (Ag) content ratio (%) may be measured by X-ray photoelectron spectroscopy (XPS), energy dispersive X-ray spectroscopy (EDS/EDX), X-ray fluorescence (XRF), or the like.

In an embodiment, the first cathode CE1 and the second cathode CE2 may further include at least any one of magnesium (Mg), ytterbium (Yb), lithium (Li), samarium (Sm), sodium (Na), or calcium (Ca), in addition to silver (Ag).

The cathodes CE of the embodiment may have a semi-transmissive characteristic and may have a light penetration depth (nm) characteristic due to the semi-transmissive characteristic. This will be described in detail later.

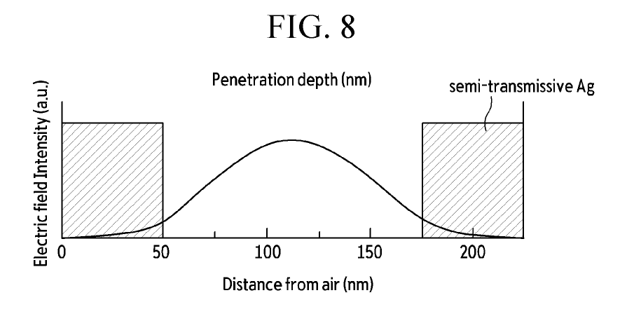

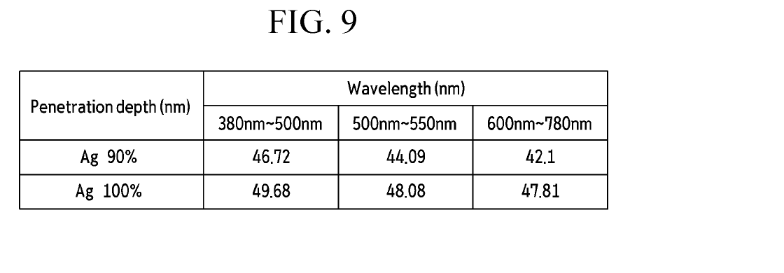

FIG. 8 is a graph illustrating the light penetration depth of a cathode of an embodiment. FIG. 9 is a diagram illustrating the light penetration depth according to the silver content of the cathode.

Referring to FIGS. 8 and 9, FIG. 8 is a graph illustrating the penetration depth (nm) of semi-transmissive silver (Ag). The X-axis of the graph represents the depth (distance from air, nm) to which light in the air penetrates into a metal structure, and the Y-axis represents electric field intensity (a.u). FIG. 9 is a diagram illustrating the penetration depth (nm) according to the silver (Ag) content of the cathode.

As illustrated in the graph of FIG. 8, in the case of the semi-transmissive Ag, some of the light penetrates into the metal. In other words, in the case of the semi-transmissive Ag, some of the light may be absorbed into the metal without being reflected at an interface of the metal.

As illustrated in the graph of FIG. 9, the semi-transmissive Ag may have a greater penetration depth value as the Ag content (%) increases.

For example, at a wavelength (600 nm to 780 nm) of red light, the penetration depth of light may be 42.1 nm when a cathode CE includes about 90% silver (Ag) and may be 47.81 ㎚ when the cathode CE includes about 100% silver (Ag).

In some aspects, at a wavelength (500 nm to 550 nm) of green light, the penetration depth of light may be 44.09 nm when the cathode CE includes about 90% silver (Ag) and may be 48.08 nm when the cathode CE includes about 100% silver (Ag).

In some aspects, at a wavelength (380 nm to 500 nm) of blue light, the penetration depth of light may be 46.72 nm when the cathode CE includes about 90% silver (Ag) and may be 49.68 nm when the cathode CE includes about 100% silver (Ag).

Generally, when a resonance distance is formed between an anode AE and a cathode CE, the penetration depth (nm) of light may have a significant effect on forming light efficiency and viewing angle characteristics. For example, as the penetration depth (nm) of light increases, the amount of light absorbed into the cathode CE may increase, which may deteriorate optical characteristics.

Accordingly, it may be important for a light emitting element ED to form an optimal resonance structure by forming a shorter resonance distance as the light penetration depth (nm) of the cathode CE increases. In addition, it may be important for the light emitting element ED to form an appropriate resonance distance according to the light penetration depth (nm) characteristic of the cathode CE and the wavelength of light emitted from a light emitting layer EL.

Referring again to FIG. 7, in an embodiment, a thickness D1 of the first light emitting layer EL1 included in the first light emitting element ED1 and a thickness D2 of the second light emitting layer EL2 included in the second light emitting element ED2 may be different. The thickness D1 of the first light emitting layer EL1 may have the same meaning as a distance D1 between the anode AE and the first cathode CE1, and the thickness D2 of the second light emitting layer EL2 may have the same meaning as a distance D2 between the anode AE and the second cathode CE2.

In an embodiment, the distance D1 between the anode AE and the first cathode CE1 may have a greater value than the distance D2 between the anode AE and the second cathode CE2.

The first cathode CE1 of an embodiment may have a lower silver (Ag) content than the second cathode CE2. Accordingly, the light penetration depth (nm) of the second cathode CE2 may have a greater value than the light penetration depth (nm) of the first cathode CE1. Therefore, in the display device 10 of the embodiment, the optimal resonance efficiency of each of the first light emitting element ED1 and the second light emitting element ED2 may be obtained by forming the resonance distance D2 in a portion overlapping the second cathode CE2 to be shorter than the resonance distance D1 in a portion overlapping the first cathode CE1.

In an embodiment, the first light emitting layer EL1 may include a first portion Ea1, a second portion Eb1 and a third portion Ec1 sequentially stacked in the third direction (Z-axis direction), and the second light emitting layer EL2 may include a first portion Ea2, a second portion Eb2 and a third portion Ec2 sequentially stacked in the third direction (Z-axis direction). The first portion Ea1, the second portion Eb1 and the third portion Ec1 included in the first light emitting layer EL1 and the first portion Ea2, the second portion Eb2 and the third portion Ec2 included in the second light emitting layer EL2 may be spaced apart from each other by the pixel defining layer 151. The pixel defining layer 151 may be located between the first portion Ea1, the second portion Eb1 and the third portion Ec1 included in the first light emitting layer EL1 and the first portion Ea2, the second portion Eb2 and the third portion Ec2 included in the second light emitting layer EL2.

In the display device 10 of the embodiment, the distance D1 between the anode AE and the first cathode CE1 and the distance D2 between the anode AE and the second cathode CE2 may be adjusted by adjusting a thickness T1 of the second portion Eb1 of the first light emitting layer EL1 and a thickness T2 of the second portion Eb2 of the second light emitting layer EL2. The thickness T1 of the second portion Eb1 of the first light emitting layer EL1 may have the same meaning as a thickness T1 of the electron transport layer mETL of the first light emitting layer EL1, and the thickness T2 of the second portion Eb2 of the second light emitting layer EL2 may have the same meaning as a thickness T2 of the electron transport layer mETL of the second light emitting layer EL2.

Reasons for adjusting the thicknesses T1 and T2 of the second portions Eb1 and Eb2 in accordance with one or more embodiments of the present disclosure will be described later.

In an example, the thickness T2 of the second portion Eb2 of the second light emitting layer EL1 may have a smaller value than the thickness T1 of the second portion Eb1 of the first light emitting layer ELb.

In an embodiment, an upper surface 1b included in the second portion Eb1 of the first light emitting layer EL1 and an upper surface 2b included in the second portion Eb2 of the second light emitting layer EL2 may be located at different respective heights in the third direction (Z-axis direction). For example, the upper surface 1b included in the second portion Eb1 may be located higher than the upper surface 2b included in the second portion Eb2.

In some aspects, the first cathode CE1 and the second cathode CE2 may be located at different respective heights in the third direction (Z-axis direction). For example, the first cathode CE1 may be located higher than the second cathode CE2.

To recapitulate with reference to FIGS. 1 through 9, in the display device 10 of the embodiment, the first cathode CE1 and the second cathode CE2 may be spaced apart from each other by the pixel defining layer 151. The pixel defining layer 151 may be located between the first cathode CE1 and the second cathode CE2. The first cathode CE1 and the second cathode CE2 may have different silver (Ag) content ratios.

Specifically, the second cathode CE2 of the embodiment may have a higher silver (Ag) content than the first cathode CE1, and the thickness T2 of the second portion Eb2 included in the second light emitting layer EL2 overlapping the second cathode CE2 may be smaller than the thickness T1 of the second portion Eb1 included in the first light emitting layer EL1 overlapping the first cathode CE1.

In other words, the second cathode CE2 of the embodiment may have a higher silver (Ag) content than the first cathode CE1, and the distance D1 between the anode AE and the first cathode CE1 may have a greater value than the distance D2 between the anode AE and the second cathode CE2.

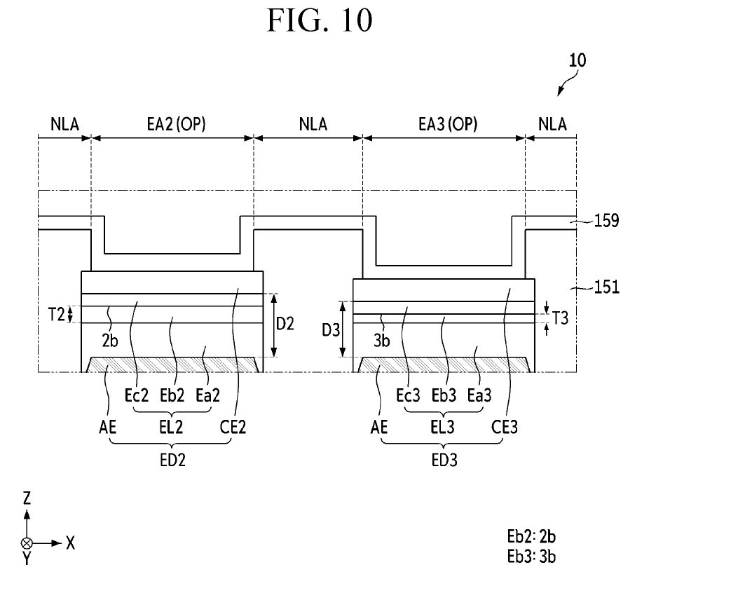

FIG. 10 is an enlarged cross-sectional view of the display element layer 150 overlapping the second emission area EA2 and the third emission area EAb in FIG. 4.

Referring to FIG. 10 in addition to FIGS. 1 through 9, in an embodiment, the third cathode CE3 and the second cathode CE2 may have different material compositions. For example, the third cathode CE3 may have a higher silver (Ag) content than the second cathode CE2. Specifically, the third cathode CE3 may have a silver (Ag) content of about 95 to 100%, and the second cathode CE2 may have a silver (Ag) content of about 95%.

In some embodiments, since the third cathode CE3 has a higher silver (Ag) content than the second cathode CE2, the light penetration depth (nm) of the third cathode CE3 may have a greater value than the light penetration depth (nm) of the second cathode CE2.

Therefore, in the display device 10 of the embodiment, an optimal resonance distance of each of the second light emitting element ED2 and the third light emitting element ED3 may be obtained by forming a distance D3 between the anode AE and the third cathode CE3 to have a smaller value than the distance D2 between the anode AE and the second cathode CE2. Redundant descriptions are omitted.

In some embodiments, in the display device 10 of the embodiment, the distance D3 between the anode AE and the third cathode CE3 and the distance D2 between the anode AE and the second cathode CE2 may be adjusted by forming a thickness T3 of the second portion Eb3 of the third light emitting layer EL3 and the thickness T2 of the second portion Eb2 of the second light emitting layer EL2 to be different from each other. For example, the thickness T3 of the second portion Eb3 included in the third light emitting layer EL3 may have a smaller value than the thickness T2 of the second portion Eb2 included in the second light emitting layer EL2. The thickness T3 of the second portion Eb3 of the third light emitting layer EL3 may have the same meaning as a thickness T3 of the electron transport layer mETL of the third light emitting layer EL3.

In an embodiment, the upper surface 2b included in the second portion Eb2 of the second light emitting layer EL2 and an upper surface 3b included in the second portion Eb3 of the third light emitting layer EL3 may be located at different respective heights in the third direction (Z-axis direction). For example, the upper surface 2b included in the second portion Eb2 may be located higher than the upper surface 3b included in the second portion Eb3.

In some aspects, the second cathode CE2 and the third cathode CE3 may be located at different respective heights in the third direction (Z-axis direction). For example, the second cathode CE2 may be located higher than the third cathode CE3.

The third cathode CE3 of the embodiment may have a higher silver (Ag) content than the second cathode CE2, and the thickness T3 of the second portion Eb3 included in the third light emitting layer EL3 overlapping the third cathode CE3 may be smaller than the thickness T2 of the second portion Eb2 included in the second light emitting layer EL2 overlapping the second cathode CE2.

In other words, the third cathode CE3 of the embodiment may have a higher silver (Ag) content than the second cathode CE2, and the distance D3 between the anode AE and the third cathode CE3 overlapping the third emission area EA3 may have a smaller value than the distance D2 between the anode AE and the second cathode CE2 overlapping the second emission area EA2.

That is, in the display device 10 of the embodiment, the optimal light efficiency and viewing angle characteristics of a light emitting element ED may be secured by forming the second portion Eb of a light emitting layer EL to have a smaller thickness as the silver (Ag) content of a cathode CE increases.

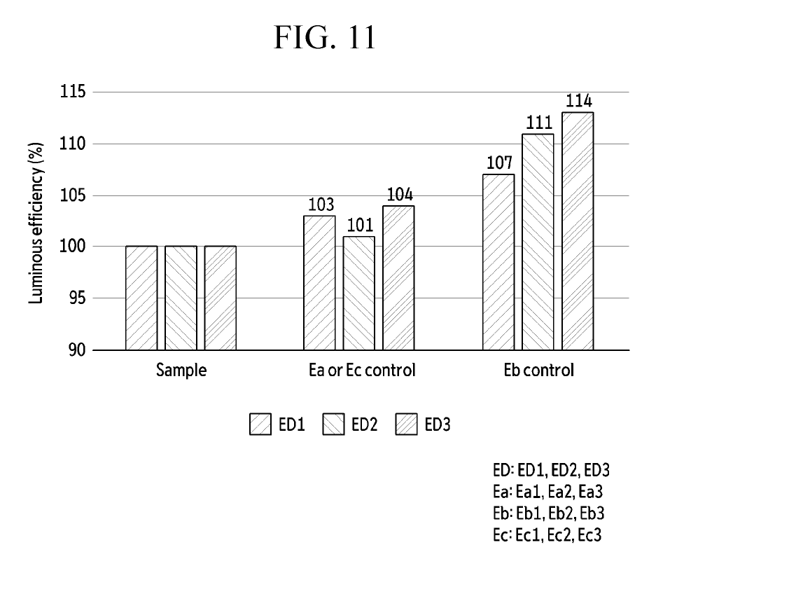

FIG. 11 is a graph illustrating the change in luminous efficiency of first through third light emitting elements when thicknesses of a first portion, a second portion and a third portion of a light emitting layer are adjusted.

Referring to FIG. 11 in addition to FIGS. 1 through 10, the graph illustrates a luminous efficiency (%) value of each of the first through third light emitting elements ED1 through ED3 when the first portion Ea, the second portion Eb and the third portion Ec of a light emitting layer EL are adjusted while the silver (Ag) content of a cathode CE is fixed. A comparative example (sample) on the graph may include a light emitting element ED whose resonance structure is not adjusted.

In an embodiment, when the thickness of the first portion Ea1 or the third portion Ec1 of the first light emitting layer EL1 of the first light emitting element ED1 was adjusted to suit the resonance structure, the luminous efficiency (%) of the first light emitting element ED1 increased by about 3% compared with the comparative example (sample). The effects of adjusting the thicknesses of the first portion Ea1 and the third portion Ec1 on luminous efficiency (%) may have similar values.

In some aspects, when the thickness of the second portion Eb1 of the first light emitting layer EL1 was adjusted, the luminous efficiency (%) of the first light emitting element ED1 increased by about 7% compared with the comparative example (sample).

In an embodiment, when the thickness of the first portion Ea2 or the third portion Ec2 of the second light emitting layer EL2 was adjusted to suit the resonance structure, the luminous efficiency (%) of the second light emitting element ED2 increased by about 1% compared with the comparative example (sample). The effects of adjusting the thicknesses of the first portion Ea2 and the third portion Ec2 on luminous efficiency (%) may have similar values.

In some aspects, when the thickness of the second portion Eb2 of the second light emitting layer EL2 was adjusted, the luminous efficiency (%) of the second light emitting element ED2 increased by about 11% compared with the comparative example (sample).

In an embodiment, when the thickness of the first portion Ea3 or the third portion Ecb of the third light emitting layer EL3 was adjusted to suit the resonance structure, the luminous efficiency (%) of the third light emitting element ED3 increased by about 4% compared with the comparative example (sample). The effects of adjusting the thicknesses of the first portion Ea3 and the third portion Ec3 on luminous efficiency (%) are similar.

In some aspects, when the thickness of the second portion Eb3 of the third light emitting layer EL3 was adjusted, the luminous efficiency (%) of the third light emitting element ED3 increased by about 14% compared with the comparative example (sample).

Therefore, it can be seen that adjusting the thickness of the second portion Eb of a light emitting layer EL has the greatest effect on improving the luminous efficiency (%) of a light emitting element ED.

To recapitulate with reference to FIGS. 1 through 11, in the display device 10 of the embodiment, the first through third cathodes CE1 through CE3 may be formed to have different silver (Ag) content, and the thicknesses T1 through T3 of the second portions Eb1 through Eb3 of the first through third light emitting layers EL1 through EL3 may be adjusted according to the silver (Ag) content of the first through third cathodes CE1 through CE3. Therefore, the first through third light emitting elements ED1 through ED3 can have optimal luminous efficiency (%) values.

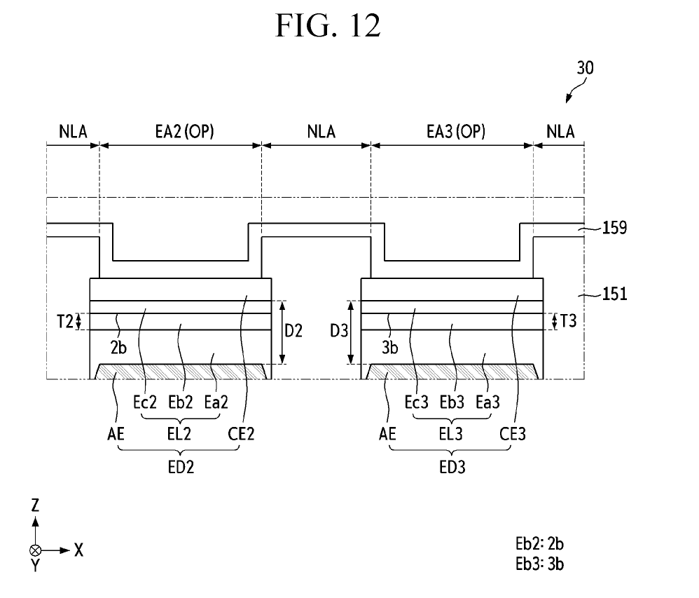

FIG. 12 is an enlarged cross-sectional view of a display element layer overlapping the second emission area EA2 and the third emission area EA3 in FIG. 4 according to an embodiment.

Referring to FIG. 12 in addition to FIGS. 1 through 11, a third light emitting element ED3 included in a display device 30 may have a different structure from the third light emitting element ED3 included in the display device 10. A description of commonalities between the display device 10 and the display device 30 will be omitted, and differences will be described herein.

In some embodiments, a third cathode CE3 and a second cathode CE2 included in the display device 30 may have the same material composition. For example, the third cathode CE3 and the second cathode CE2 may have a silver (Ag) content of about 95% to 100%.

The third cathode CE3 included in the display device 30 may have a higher silver (Ag) content than a first cathode CE1, and the first cathode CE1 may have a silver (Ag) content of about 90% to about 95%. The first cathode CE1 included in the display device 30 may be identical to the first cathode CE1 included in the display device 10. Redundant descriptions are omitted.

In some embodiments, a distance D3 between an anode AE and the third cathode CE3 included in the display device 30 may have the same value as a distance D2 between an anode AE and the second cathode CE2. The distance D3 between the anode AE and the third cathode CE3 and the distance D2 between the anode AE and the second cathode CE2 may each have a smaller value than a distance D1 between an anode AE and the first cathode CE1. Redundant descriptions are omitted.

In some embodiments, in the display device 30, a thickness T3 of a second portion Eb3 of a third light emitting layer EL3 and a thickness T2 of a second portion Eb2 of a second light emitting layer EL2 may have the same value, and the thickness T3 of the second portion Eb3 of the third light emitting layer EL3 and the thickness T2 of the second portion Eb2 of the second light emitting layer EL2 may each have a smaller value than a thickness T1 of a second portion Eb1 of a first light emitting layer EL1. Redundant descriptions are omitted.

In some embodiments, an upper surface 2b included in the second portion Eb2 of the second light emitting layer EL2 and an upper surface 3b included in the second portion Eb3 of the third light emitting layer EL3 in the display device 30 may be located on the same line in the first direction (X-axis direction), and the second cathode CE2 and the third cathode CE3 may be located on the same line in the first direction (X-axis direction). However, the upper surface 3b included in the second portion Eb3 of the third light emitting layer EL3 may be located lower than an upper surface 1b included in the second portion Eb1 of the first light emitting layer EL1. Redundant descriptions are omitted.

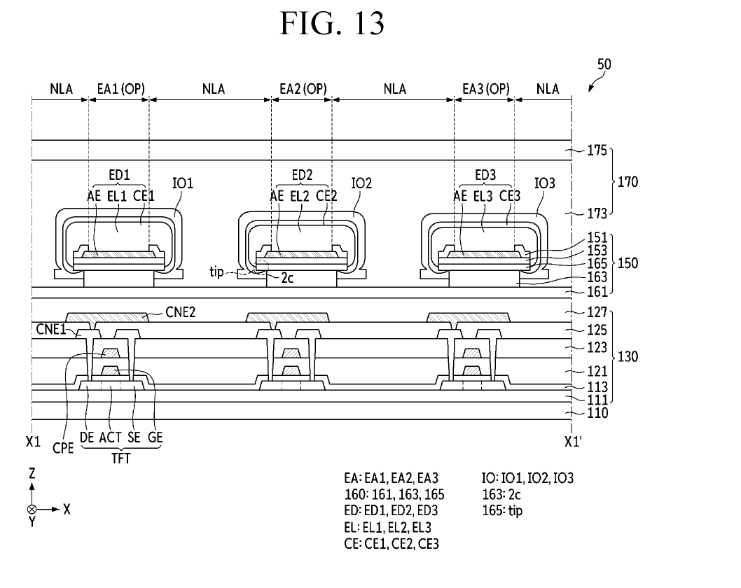

FIG. 13 is a schematic cross-sectional view taken along line X1-X1’ of FIG. 3 according to an embodiment.

Referring to FIG. 13 in addition to FIGS. 1 through 12, a substrate 110 and a thin-film transistor layer 130 included in a display device 50 are the same as the substrate 110 and the thin-film transistor layer 130 included in the display device 10. A description of common structures of the display device 50 and the display device 10 will be omitted, and differences will be described herein.

In some embodiments, a display element layer 150 included in the display device 50 may include a bank structure 160, an element insulating layer 153, a pixel defining layer 151, light emitting elements ED, and element inorganic layers IO.

The bank structure 160 included in the display device 50 may be located on a second via layer 127. The bank structure 160 may be located in portions overlapping emission areas EA. The bank structure 160 may be formed in multiple pieces, and the multiple pieces of the bank structure 160 may be spaced apart from each other.

The bank structure 160 included in the display device 50 may include a first bank layer 161, a second bank layer 163, and a third bank layer 165. The first bank layer 161, the second bank layer 163, and the third bank layer 165 may be sequentially stacked in the third direction (Z-axis direction).

The first bank layer 161 may be located on the second via layer 127. The first bank layer 161 may cover the entire surface of the second via layer 127 in portions overlapping the emission areas EA and a non-emission area NLA.

The first bank layer 161 may assist in applying a low-potential voltage to cathodes CE.

The first bank layer 161 may include a conductive metal having etch resistance. For example, the first bank layer 161 may be titanium (Ti).

The second bank layer 163 may be located on the first bank layer 161 to contact the first bank layer 161. The second bank layer 163 may be electrically connected to the first bank layer 161. The second bank layer 163 may assist in electrically connecting the first bank layer 161 to the cathodes CE.

The second bank layer 163 may include a metal having high electrical conductivity. For example, the second bank layer 163 may include aluminum (Al).

The second bank layer 163 located in a portion overlapping a first emission area EA1, the second bank layer 163 located in a portion overlapping a second emission area EA2, and the second bank layer 163 located in a portion overlapping a third emission area EA3 in the display device 50 may be electrically connected by the first bank layer 161.

The third bank layer 165 may be located on the second bank layer 163. The third bank layer 165 may include a conductive metal having etch resistance. For example, the third bank layer 165 may be titanium (Ti).

The third bank layer 165 located in the portion overlapping the first emission area EA1, the third bank layer 165 located in the portion overlapping the second emission area EA2, and the third bank layer 165 located in the portion overlapping the third emission area EA3 in the display device 50 may be electrically connected through the second bank layer 163 and the first bank layer 161.

The second bank layer 163 included in the display device 50 may include side surfaces 2c facing the non-emission area NLA, and the third bank layer 165 may include tips protruding toward the non-emission area NLA more than the side surfaces 2c of the second bank layer 163.

Accordingly, the side surfaces 2c of the second bank layer 163 and the tips of the third bank layer 165 may form undercuts, and the bank structure 160 may have an overhang structure.

Since the bank structure 160 includes the tips, the display device 50 may include a first light emitting element ED1, a second light emitting element ED2, and a third light emitting element ED3 spaced apart from each other by a photolithography process without a separate fine metal mask in a manufacturing process.

The element insulating layer 153 included in the display device 50 may be located on the third bank layer 165. The element insulating layer 153 may cover the entire upper surface of the third bank layer 165. The element insulating layer 153 may overlap the tips of the third bank layer 165 in the third direction (Z-axis direction).

The element insulating layer 153 may insulate the bank structure 160 from anodes AE.

The element insulating layer 153 may include an inorganic insulating material. For example, the element insulating layer 153 may include at least one of silicon nitride, silicon oxide, and silicon oxynitride.

The pixel defining layer 151 included in the display device 50 may be located on the element insulating layer 153. The pixel defining layer 151 may define emission openings OP and may expose the anodes AE in portions overlapping the emission openings OP. The pixel defining layer 151 may surround the emission openings OP and may cover edges of the anodes AE.

The pixel defining layer 151 included in the display device 50 may overlap the tips of the third bank layer 165 in the third direction (Z-axis direction).

The pixel defining layer 151 included in the display device 50 may include an inorganic insulating material. For example, the pixel defining layer 151 may include at least one of silicon nitride, silicon oxide, and silicon oxynitride.

The light emitting elements ED included in the display device 50 may be located on the bank structure 160 and the element insulating layer 153. The light emitting elements ED of an embodiment may overlap the bank structure 160 and the element insulating layer 153 in the third direction (Z-axis direction).

Since the display device 50 is applied to a high-resolution electronic device 1, the light emitting elements ED included in the display element layer 150 may be specified to lie within a narrow area with an appropriate distance secured between the light emitting elements ED. Accordingly, the light emitting elements ED may be formed on the bank structure 160, and thus the display device 50 may include a plurality of light emitting elements ED located within a narrow area with an appropriate distance secured between the light emitting elements ED.

The light emitting elements ED may include the first light emitting element ED1 located in the first emission area EA1, the second light emitting element ED2 located in the second emission area EA2, and the third light emitting element ED3 located in the third emission area EA3. The first light emitting element ED1, the second light emitting element ED2, and the third light emitting element ED3 may be spaced apart from each other.

The first light emitting element ED1 may include an anode AE, a first light emitting layer EL1, and a first cathode CE1. The second light emitting element ED2 may include an anode AE, a second light emitting layer EL2, and a second cathode CE2. The third light emitting element ED3 may include an anode AE, a third light emitting layer EL3, and a third cathode CE3.

The first light emitting element ED1, the second light emitting element ED2, and the third light emitting element ED3 may emit light of different colors. For example, the first light emitting element ED1 may emit red light, the second light emitting element ED2 may emit green light, and the third light emitting element ED3 may emit blue light.

The anodes AE included in the display device 50 may be located on the element insulating layer 153. The anodes AE may contact the element insulating layer 153. As described herein, the anodes AE may be spaced apart from the bank structure 160 by the element insulating layer 153.

Light emitting layers EL included in the display device 50 may be located on the anodes AE. The light emitting layers EL may be located in the portions overlapping the emission areas EA and the non-emission area NLA.

In some embodiments, the light emitting layers EL may contact the anodes AE in the portions overlapping the emission openings OP and may cover an upper surface of the pixel defining layer 151 and side surfaces of the pixel defining layer 151, which face the non-emission area NLA, in the portion overlapping the non-emission area NLA. In some aspects, the light emitting layers EL may contact side surfaces of the element insulating layer 153 which face the non-emission area NLA.

The light emitting layers EL may include the first light emitting layer EL1, the second light emitting layer EL2, and the third light emitting layer EL3. The first light emitting layer EL1 may be located in the portion overlapping the first emission area EA1, the second light emitting layer EL2 may be located in the portion overlapping the second emission area EA2, and the third light emitting layer EL3 may be located in the portion overlapping the third emission area EA3. The first light emitting layer EL1, the second light emitting layer EL2, and the third light emitting layer EL3 may be spaced apart from each other in the portion overlapping the non-emission area NLA.

In a process of manufacturing the display device 50, the light emitting layers EL included in the display device 50, that is, the first light emitting layer EL1, the second light emitting layer EL2, and the third light emitting layer EL3 can be formed by a photolithography process without using a separate fine metal mask because the bank structure 160 includes the tips.

Since the light emitting layers EL included in the display device 50 are formed by a photolithography process in the manufacturing process, the first through third light emitting layers EL1 through EL3 may have different thickness characteristics. This will be described in detail later.

The cathodes CE included in the display device 50 may be located on the light emitting layers EL. The cathodes CE may be located in the portions overlapping the emission areas EA and the non-emission area NLA. The cathodes CE may entirely cover the light emitting layers EL.

In some embodiments, the cathodes CE may contact the tips of the third bank layer 165.

The cathodes CE may include the first cathode CE1, the second cathode CE2, and the third cathode CE3. The first cathode CE1 may be located in the portion overlapping the first emission area EA1, the second cathode CE2 may be located in the portion overlapping the second emission area EA2, and the third cathode CE3 may be located in the portion overlapping the third emission area EA3. The first cathode CE1, the second cathode CE2, and the third cathode CE3 may be spaced apart from each other.

In some embodiments, the first cathode CE1, the second cathode CE2, and the third cathode CE3 included in the display device 50 may not be directly connected, but may be electrically connected through the bank structure 160. In other words, the first cathode CE1, the second cathode CE2 and the third cathode CE3 may contact the third bank layer 165 and may be electrically connected to each other through the second bank layer 163 and the first bank layer 161 which are electrically connected to the third bank layer 165.

In the process of manufacturing the display device 50, the cathodes CE included in the display device 50, that is, the first cathode CE1, the second cathode CE2, and the third cathode CE3 can be formed by a photolithography process without using a separate fine metal mask because the bank structure 160 includes the tips. Accordingly, the first through third cathodes CE1 through CE3 may have different material compositions. This will be described in detail later.

The element inorganic layers IO included in the display device 50 may be located on the light emitting elements ED. The element inorganic layers IO may completely cover the light emitting elements ED and prevent oxygen or moisture from penetrating into the light emitting elements ED.

The element inorganic layers IO may include an inorganic insulating material. For example, the element inorganic layers IO may include any one of silicon nitride, silicon oxide, or silicon oxynitride.

The element inorganic layers IO may include a first element inorganic layer IO1, a second element inorganic layer IO2, and a third element inorganic layer IO3. The first element inorganic layer IO1 may be located on the first light emitting element ED1 in the first emission area EA1. The second element inorganic layer IO2 may be located on the second light emitting element ED2 in the second emission area EA2. The third element inorganic layer IO3 may be located on the third light emitting element ED3 in the third emission area EA3. The first element inorganic layer IO1, the second element inorganic layer IO2, and the third element inorganic layer IO3 may be spaced apart from each other in the portion overlapping the non-emission area NLA.

In the drawing, the first element inorganic layer IO1, the second element inorganic layer IO2, and the third element inorganic layer IO3 appear to be formed in the same layer. However, in process of manufacturing the display device 50, the first element inorganic layer IO1 may be formed after the first light emitting element ED1 is formed, the second element inorganic layer IO2 may be formed after the second light emitting element ED2 is formed, and the third element inorganic layer IO3 may be formed after the third light emitting element ED3 is formed.

The element inorganic layers IO may contact the side surfaces 2c of the second bank layer 163. The element inorganic layers IO may be spaced apart from the first bank layer 161 in the third direction (Z-axis direction).

A thin-film encapsulation layer 170 may be located on the display element layer 150. The thin-film encapsulation layer 170 may include an organic encapsulation layer 173 and an inorganic encapsulation layer 175.

The organic encapsulation layer 173 of an embodiment may be located on the element inorganic layers IO. For example, the organic encapsulation layer 173 may entirely contact and cover the first element inorganic layer IO1, the second element inorganic layer IO2, and the third element inorganic layer IO3.

The organic encapsulation layer 173 may flatten steps formed according to the profile of the structures under the organic encapsulation layer 173. Redundant descriptions are omitted.

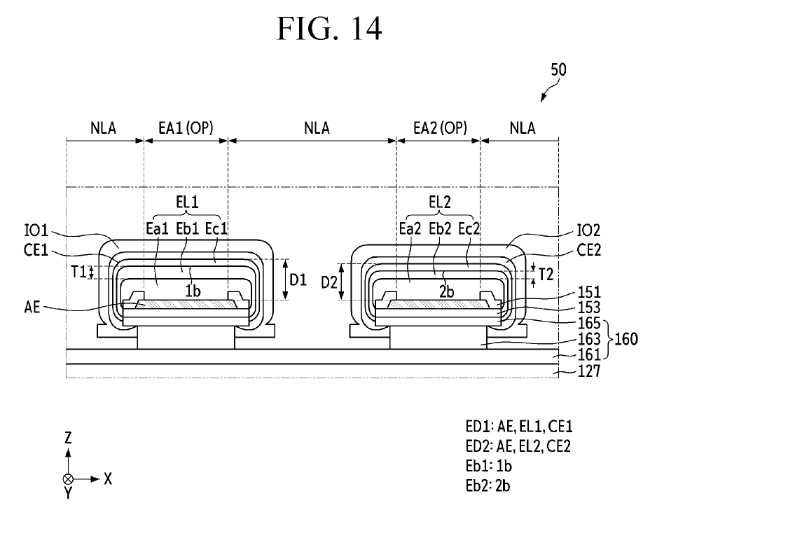

FIG. 14 is an enlarged cross-sectional view of the display element layer 150 overlapping the first emission area EA1 and the second emission area EA2 in FIG. 13.

Referring to FIG. 14 in addition to FIGS. 1 through 13, the anode AE, the first light emitting layer EL1 and the first cathode CE1 included in the first light emitting element ED1 and the anode AE, the second light emitting layer EL2 and the second cathode CE2 included in the second light emitting element ED2 in the display device 50 may be spaced apart from each other in the first direction (X-axis direction).

As described herein, the cathodes CE included in the display device 50 may be formed by a photolithography process to have different material compositions. In other words, the silver (Ag) content of the first cathode CE1 and the silver (Ag) content of the second cathode CE2 may be different from each other.

Specifically, the first cathode CE1 may have a lower silver (Ag) content than the second cathode CE2. For example, the first cathode CE1 may include about 90% to 95% silver (Ag), and the second cathode CE2 may include about 95% or more silver (Ag).

The first cathode CE1 and the second cathode CE2 included in the display device 50 may further include at least any one of magnesium (Mg), ytterbium (Yb), lithium (Li), samarium (Sm), sodium (Na), or calcium (Ca), in addition to silver (Ag).

The cathodes CE included in the display device 50 may have a semi-transmissive characteristic and may have a penetration depth (nm) due to the semi-transmissive characteristic. Redundant descriptions are omitted.

A thickness D1 of the first light emitting layer EL1 and a thickness D2 of the second light emitting layer EL2 in the display device 50 may be different. The thickness D1 of the first light emitting layer EL1 may have the same meaning as a distance D1 between the anode AE and the first cathode CE1. The thickness D2 of the second light emitting layer EL2 may have the same meaning as a distance D2 between the anode AE and the second cathode CE2.

The distance D1 between the anode AE and the first cathode CE1 included in the display device 50 may have a greater value than the distance D2 between the anode AE and the second cathode CE2.

As described herein, the first cathode CE1 of an embodiment may have a lower silver (Ag) content than the second cathode CE2. Accordingly, the light penetration depth (nm) of the second cathode CE2 may have a greater value than the light penetration depth (nm) of the first cathode CE1. Therefore, in the display device 50, optimal optical characteristics for the first light emitting element ED1 and the second light emitting element ED2 may be achieved by forming the resonance distance D2 in a portion overlapping the second cathode CE2 to be shorter than the resonance distance D1 in a portion overlapping the first cathode CE1.

The first light emitting layer EL1 included in the display device 50 may include a first portion Ea1, a second portion Eb1, and a third portion Ec1 sequentially stacked in the third direction (Z-axis direction). The second light emitting layer EL2 may include a first portion Ea2, a second portion Eb2, and a third portion Ec2. The first portion Ea1, the second portion Eb1 and the third portion Ec1 included in the first light emitting layer EL1 and the first portion Ea2, the second portion Eb2 and the third portion Ec2 included in the second light emitting layer EL2 may be spaced apart from each other in the first direction (X-axis direction).

In the display device 50, the distance D1 between the anode AE and the first cathode CE1 and the distance D2 between the anode AE and the second cathode CE2 may be adjusted by adjusting a thickness T1 of the second portion Eb1 of the first light emitting layer EL1 and a thickness T2 of the second portion Eb2 of the second light emitting layer EL2. For example, the thickness T2 of the second portion Eb2 of the second light emitting layer EL2 may have a smaller value than the thickness T1 of the second portion Eb1 of the first light emitting layer EL1.

An upper surface 1b included the second portion Eb1 of the first light emitting layer EL1 and an upper surface 2b included in the second portion Eb2 of the second light emitting layer EL2 in the display device 50 may be located at different respective heights in the third direction (Z-axis direction). For example, the upper surface 1b included in the second portion Eb1 may be located higher than the upper surface 2b included in the second portion Eb2.

In some aspects, the first cathode CE1 and the second cathode CE2 may be located at different respective heights in the third direction (Z-axis direction). For example, the first cathode CE1 may be located higher than the second cathode CE2. Redundant descriptions are omitted.

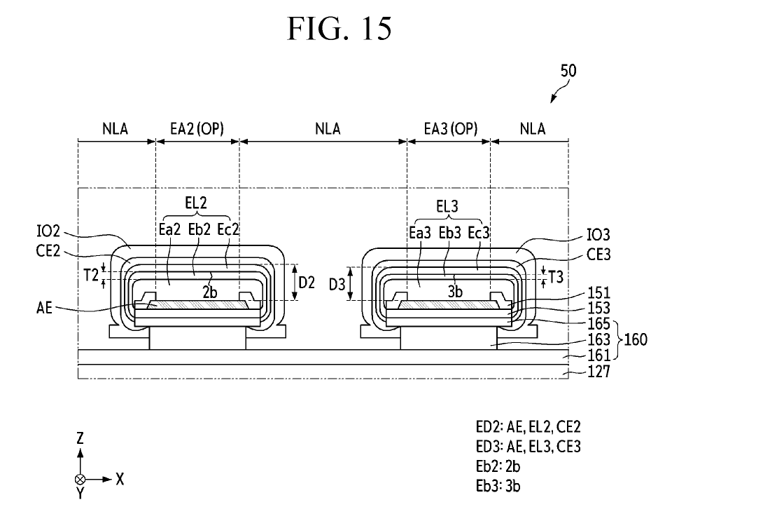

FIG. 15 is an enlarged cross-sectional view of the display element layer 150 overlapping the second emission area EA2 and the third emission area EA3 in FIG. 13.

Referring to FIG. 15 in addition to FIGS. 1 through 14, the third cathode CE3 and the second cathode CE2 included in the display device 50 may have different material compositions. The third cathode CE3 may have a higher silver (Ag) content than the second cathode CE2. For example, the third cathode CE2 may have a silver (Ag) content of about 95% to 100%, and the second cathode CE2 may have a silver (Ag) content of about 95%.

Since the third cathode CE3 included in the display device 50 includes a higher silver (Ag) content than the second cathode CE2, the light penetration depth (nm) of the third cathode CE3 may have a greater value than the light penetration depth (nm) of the second cathode CE2.

Therefore, in the display device 50, an optimal resonance distance of each of the second light emitting element ED2 and the third light emitting element ED3 may be achieved by forming a distance D3 between the anode AE and the third cathode CE3 to have a smaller value than the distance D2 between the anode AE and the second cathode CE2.

In the display device 50, the distance D3 between the anode AE and the third cathode CE3 and the distance D2 between the anode AE and the second cathode CE2 may be adjusted by forming a thickness T3 of the second portion Eb3 of the third light emitting layer EL3 and the thickness T2 of the second portion Eb2 of the second light emitting layer EL2 to be different from each other. For example, the thickness T3 of the second portion Eb3 included in the third light emitting layer EL3 may have a smaller value than the thickness T2 of the second portion Eb2 included in the second light emitting layer EL2.

The upper surface 2b included in the second portion Eb2 of the second light emitting layer EL2 and an upper surface 3b included in the second portion Eb3 of the third light emitting layer EL3 in the display device 50 may be located at different respective heights in the third direction (Z-axis direction). For example, the upper surface 2b included in the second portion Eb2 may be located higher than the upper surface 3b included in the second portion Eb3.

In some aspects, the second cathode CE2 and the third cathode CE3 may be located at different respective heights in the third direction (Z-axis direction). For example, the second cathode CE2 may be located higher than the third cathode CE3.

That is, in the display device 50, the optimal light efficiency and viewing angle characteristics of a light emitting element ED may be secured by forming the second portion Eb of a light emitting layer EL to have a smaller thickness as the silver (Ag) content of a cathode CE increases.

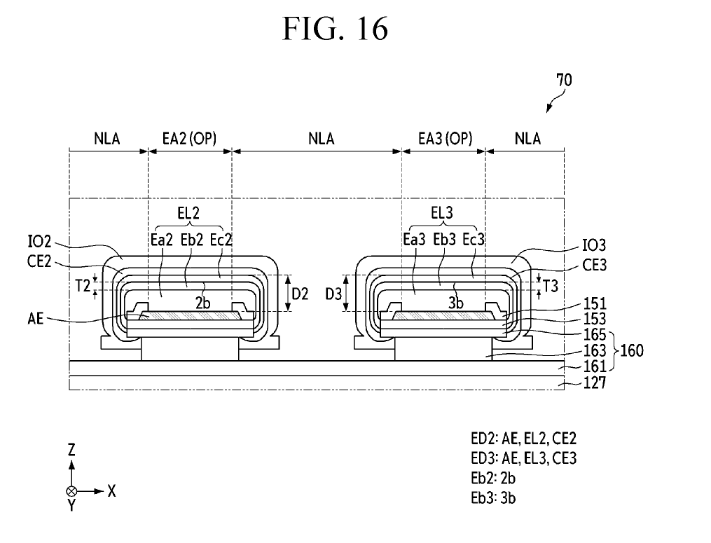

FIG. 16 is an enlarged cross-sectional view of a display element layer overlapping the second emission area EA2 and the third emission area EA3 in FIG. 13 according to an embodiment.

Referring to FIG. 16 in addition to FIGS. 1 through 15, a third light emitting element ED3 included in a display device 70 may have a different structure from the third light emitting element ED3 included in the display device 50. A description of commonalities between the display device 50 and the display device 70 will be omitted, and differences will be described herein.

A third cathode CE3 and a second cathode CE2 included in the display device 70 may have the same material composition. For example, the third cathode CEb and the second cathode CE2 may have a silver (Ag) content of about 95% to 100%.

The third cathode CE3 included in the display device 70 may have a higher silver (Ag) content than a first cathode CE1, and the first cathode CEb may have a silver (Ag) content of about 90% to 95%. The first cathode CE1 included in the display device 70 may be identical to the first cathode CE1 included in the display device 50. Redundant descriptions are omitted.

In some embodiments, a distance D3 between an anode AE and the third cathode CE3 included in the display device 70 may have the same value as a distance D2 between an anode AE and the second cathode CE2. The distance D3 between the anode AE and the third cathode CE3 and the distance D2 between the anode AE and the second cathode CE2 may each have a smaller value than a distance D1 between an anode AE and the first cathode CE1. Redundant descriptions are omitted.

In some embodiments, in the display device 70, a thickness T3 of a second portion Eb3 of a third light emitting layer EL3 and a thickness T2 of a second portion Eb2 of a second light emitting layer EL2 may have the same value, and the thickness T3 of the second portion Eb3 of the third light emitting layer EL3 and the thickness T2 of the second portion Eb2 of the second light emitting layer EL2 may each have a smaller value than a thickness T1 of a second portion Eb1 of a first light emitting layer EL1. Redundant descriptions are omitted.

An upper surface 2b included in the second portion Eb2 of the second light emitting layer EL2 and an upper surface 3b included in the second portion Eb3 of the third light emitting layer EL3 in the display device 70 may be located on the same line in the first direction (X-axis direction), and the second cathode CE2 and the third cathode CE3 may be located on the same line in the first direction (X-axis direction). However, the upper surface 3b included in the second portion Eb3 of the third light emitting layer EL3 may be located lower than an upper surface 1b included in the second portion Eb1 of the first light emitting layer EL1. Redundant descriptions are omitted.

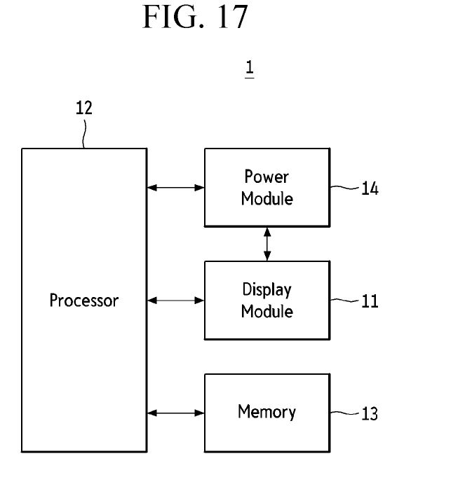

FIG. 17 is a block diagram of an electronic device 1 according to an embodiment.

Referring to FIG. 17 in addition to FIGS. 1 through 16, a display device 10 according to an embodiment can be applied to various electronic devices 1. An electronic device b according to an embodiment may include the display device 10, 30, 50 or 70 described herein and may further include modules or devices having other additional functions, in addition to the display device 10, 30, 50 or 70.

The electronic device 1 according to the embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information supportive of the operation of the processor 12 or the display module 11. In an example in which the processor 12 executes an application stored in the memory 13, an image data signal and/or an input control signal may be transmitted to the display module 11, and the display module 11 may process the received signal and output image information through a display screen.

The power module 14 may include a power supply module, such as a power adapter or a battery device, and a power conversion module. The power conversion module may generate power for the operation of the electronic device 1 by converting power supplied by the power supply module.

At least one of the elements of the electronic device 1 described herein may be included in a display device according to the above-described embodiments. In some aspects, some of individual modules functionally included in one module may be included in the display device, and other modules may be provided separately from the display device. For example, the display device may include the display module 11, and the processor 12, the memory 13 and the power module 14 may be provided not in the display device but in the form of other devices within the electronic device 1.

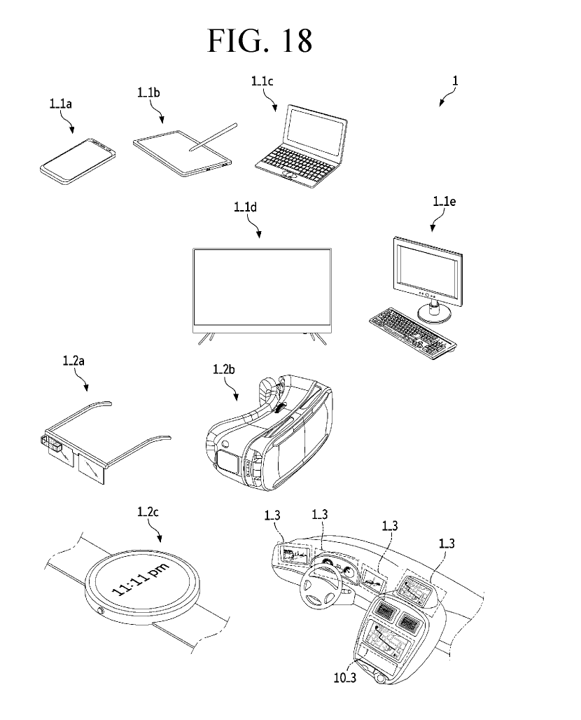

FIG. 18 is a schematic diagram of electronic devices according to various embodiments.

Referring to FIG. 18, various electronic devices 1 to which the display devices 10, 30, 50 and 70 according to the embodiments are applied may include image display electronic devices such as a smartphone 1_1a, a tablet PC 1_1b, a laptop 1_1c, a television 1_1d, and a desk monitor 1_1e. In some aspects, the various electronic devices 1 to which the display devices 10, 30, 50 and 70 according to the embodiments are applied may include wearable electronic devices including a display module, such as smart glasses 1_2a, a head-mounted display 1_2b and a smart watch 1_2c, and vehicle electronic devices 1_3 including a display module, such as a center information display (CID) and a room mirror display placed on an instrument cluster, center fascia and dashboard of a vehicle.

Embodiments of the disclosure should not be construed as being limited to the embodiments set forth herein. Rather, the example embodiments are provided such that this disclosure will be thorough and complete and will fully convey the concept of the invention to those skilled in the art.

While the invention has been particularly illustrated and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate comprising an emission area and a non-emission area;
a plurality of anodes located on the emission area of the substrate;
a light emitting layer located on the plurality of anodes and comprising a first light emitting layer and a second light emitting layer spaced apart from each other; and
a cathode comprising:
a first cathode located on the first light emitting layer; and
a second cathode located on the second light emitting layer and spaced apart from the first cathode,
wherein:
the cathode comprises 90% to 100% silver (Ag),
silver content of the first cathode and silver content of the second cathode are different from each other, and
a thickness of an electron transport layer of the first light emitting layer and a thickness of an electron transport layer of the second light emitting layer are different from each other.

2. The display device of claim 1, wherein:
the silver content of the second cathode is higher than the silver content of the first cathode, and
the thickness of the electron transport layer of the second light emitting layer has a smaller value than the thickness of the electron transport layer of the first light emitting layer.

3. The display device of claim 2, further comprising:
a third light emitting layer spaced apart from the first light emitting layer and the second light emitting layer; and
a third cathode located on the third light emitting layer and spaced apart from the first cathode and the second cathode,
wherein:
silver content of the third cathode is higher than the silver content of the second cathode, and
a thickness of an electron transport layer of the third light emitting layer has a smaller value than the thickness of the electron transport layer of the second light emitting layer.

4. The display device of claim 2, further comprising:
a third light emitting layer spaced apart from the first light emitting layer and the second light emitting layer; and
a third cathode located on the third light emitting layer and spaced apart from the first cathode and the second cathode,
wherein:
silver content of the third cathode is equal to the silver content of the second cathode, and
a thickness of an electron transport layer of the third light emitting layer is equal to the thickness of the electron transport layer of the second light emitting layer.

5. The display device of claim 2, further comprising a pixel defining layer located on the cathode and defining one or more emission openings,
wherein:
the first light emitting layer and the second light emitting layer are spaced apart from each other by a portion of the pixel defining layer located between the first light emitting layer and the second light emitting layer, and
the first cathode and the second cathode are spaced apart from each other by a portion of the pixel defining layer located between the first cathode and the second cathode.

6. The display device of claim 5, further comprising a cathode auxiliary electrode located on the cathode,
wherein the cathode auxiliary electrode:
contacts the first cathode at a portion of the cathode auxiliary electrode overlapping an emission opening associated with the first cathode,
contacts the second cathode at a portion of the cathode auxiliary electrode overlapping an emission opening associated with the second cathode, and
electrically connects the first cathode and the second cathode.

7. The display device of claim 2, wherein a distance between the first cathode and a first anode of the plurality of anodes has a greater value than a distance between the second cathode and a second anode of the plurality of anodes.

8. The display device of claim 2, wherein the light emitting layer comprises:
a first portion located on the anodes and comprising a hole transport layer and an organic light emitting layer;
a second portion located on the first portion and comprising the electron transport layer of the first light emitting layer and the electron transport layer of the second light emitting layer; and
a third portion located between the second portion and the cathode and comprising an electron injection layer.

9. The display device of claim 8, wherein the first portion of the light emitting layer comprises:
a plurality of organic light emitting layers; and
a charge transport layer located between the plurality of organic light emitting layers.

10. The display device of claim 9, wherein a thickness of the second portion of the first light emitting layer has a greater value than a thickness of a second portion of the second light emitting layer.

11. The display device of claim 2, further comprising a bank structure located between the substrate and the anodes, wherein the bank structure comprises:
a first bank layer;
a second bank layer; and
a third bank layer comprising a tip protruding toward the non-emission area more than a side surface of the second bank layer.

12. The display device of claim 11, wherein:
the light emitting layer and the cathode are located on the bank structure, and
the cathode contacts the tip of the third bank layer.

13. The display device of claim 12, further comprising:
an element insulating layer located between the anodes and the bank structure; and
a pixel defining layer located on the element insulating layer and covering edges of the anodes,
wherein the light emitting layer covers upper and side surfaces of the pixel defining layer and contacts side surfaces of the element insulating layer.

14. The display device of claim 1, wherein the cathode has a semi-transmissive characteristic.

15. The display device of claim 1, wherein the cathode further comprises at least any one of magnesium, ytterbium, lithium, samarium, sodium, or calcium.

16. An electronic device comprising:
at least one display device comprising a substrate which comprises an emission area and a non-emission area; and
at least any one of a display module, a processor, a memory, or a power module connected to the display device,
wherein the at least one display device comprises:
a plurality of anodes located on the emission area of the substrate;
a light emitting layer located on the plurality of anodes and comprising a first light emitting layer and a second light emitting layer spaced apart from each other; and
a cathode comprising:
a first cathode located on the first light emitting layer; and
a second cathode located on the second light emitting layer and spaced apart from the first cathode,
wherein:
the cathode comprises 90% to 100% silver (Ag),
silver content of the first cathode and silver content of the second cathode are different from each other, and
a thickness of an electron transport layer of the first light emitting layer and a thickness of an electron transport layer of the second light emitting layer are different from each other.

17. The electronic device of claim 16, wherein:
the silver content of the second cathode is higher than the silver content of the first cathode, and
the thickness of the electron transport layer of the second light emitting layer has a smaller value than the thickness of the electron transport layer of the first light emitting layer.

18. The electronic device of claim 17, further comprising:
a third light emitting layer spaced apart from the first light emitting layer and the second light emitting layer; and
a third cathode located on the third light emitting layer and spaced apart from the first cathode and the second cathode,
wherein:
silver content of the third cathode is higher than the silver content of the second cathode, and
a thickness of an electron transport layer of the third light emitting layer has a smaller value than the thickness of the electron transport layer of the second light emitting layer.

19. The electronic device of claim 18, further comprising:
a third light emitting layer spaced apart from the first light emitting layer and the second light emitting layer; and
a third cathode located on the third light emitting layer and spaced apart from the first cathode and the second cathode,
wherein:
silver content of the third cathode is equal to the silver content of the second cathode, and
a thickness of an electron transport layer of the third light emitting layer is equal to the thickness of the electron transport layer of the second light emitting layer.

20. The electronic device of claim 16, wherein the cathode has a semi-transmissive characteristic and further comprises at least any one of magnesium, ytterbium, lithium, samarium, sodium, or calcium.
